(19) United States
(12) Patent Application Publication
(10) Pub. No.: US 2026/0304673 A1
(43) Pub. Date: Oct. 1, 2026

(54) MULTI-DIRECTIONAL ATTACHMENT AND REMOVAL OF ELECTRONICS TRAY WITHIN ELECTRONICS RACKS

(71) Applicant: AMD Design, LLC, Wilmington, DE (US)

(72) Inventors: Chen AN, Bergenfield, NJ (US); Yuan ZHANG, Hackensack, NJ (US)

(73) Assignee: AMD Design, LLC, Wilmington, DE (US)

(21) Appl. No.: 19/092,301

(22) Filed: Mar. 27, 2025

(51) Int. Cl. H05K 7/14

(52) U.S. Cl. CPC H05K 7/1489

(57) ABSTRACT

A method and system for multidirectional installation and removal of electronics trays comprising electronic components into and from electronics racks. The electronics trays include one or more attachment mechanisms at each end of the electronics tray for securing the electronics tray in the electronics rack and permit multi-directional installation and removal of the electronics tray from the electronics rack. The attachment mechanism at each end of the electronics tray includes two engagement members biased to an extended position that are moveable to a retracted position to facilitate and permit movement of the electronics tray in the electronics rack.

### FIELD

This disclosure is directed to multi-directional installation, attachment, and/or removal of electronics trays in electronics racks, including multidirectional attachment/removal mechanisms, to facilitate easier installment and removal of electronics trays from electronic racks, for example, server and/or networking racks.

### BACKGROUND

An electronics rack, e.g., a server rack, usually includes a plurality of trays of electronic components. The electronics tray includes a plurality of electronic components (e.g., hard drives, integrated circuits, networking equipment, etc.) often assembled on printed circuit boards arranged on the electronic trays where the electronic trays are inserted, installed, and/or connected together in the electronic racks. For example, a plurality of hard drives and other electronic components are arranged on a printed circuit board that is arranged on an electronics tray usually configured as a horizontal plate or plane. The tray often includes one or more electrical connectors so that upon installation of the tray in the electronics rack the electronic components and/or tray is electrically connected to one or more other trays and/or other electronic components in the electronics rack.

The electronic trays are usually installed in the electronics racks where they may be removed for maintenance, repair, and/or replacement. Electronic trays are installed generally by sliding in and out of the chassis of the electronic racks in a singular direction and fixing within the electronics rack, which can make installation, maintenance, repair and/or replacement of the electronic trays and/or electronic components difficult, especially when one side of the electronics rack is close to a wall or any kind of physical barrier. A multi-directional electronics tray that permits installation, locking, connection, and/or removal from the electronics rack from multiple directions would be advantageous.

### SUMMARY

An electronics tray that contains a plurality of electronic components (e.g., hard drives, integrated circuits, etc.) positioned and/or arranged on one or more printed circuit boards and configured to permit installation in and/or removal from electronics racks from multiple directions is disclosed. In an embodiment, ends of the electronics tray, e.g., a front end and a rear end, include respective attachment mechanisms for securing, containing, and/or attaching the electronics tray in position in an electronics rack that permits installation in and/or removal from the electronics rack from multiple directions (e.g., that is capable of multi-directional removal and installation) is disclosed as well as a method of installing a multi-directional tray in, and removing a multi-directional tray from, an electronics rack.

In one or more configurations an electronics tray containing multiple electronic components is disclosed where the electronics tray includes attachment mechanisms at respective ends of the electronics tray to contain the electronics tray in an electronics rack and permit multi-directional installation and removal of the electronics tray from the electronics rack. In an arrangement, the attachment mechanism at each end of the electronics rack includes a biasing mechanism wherein the biasing mechanism biases the attachment mechanism to an extended position where the attachment mechanism is contained within a securing portion of the electronics rack to secure the electronics tray in the electronics rack.

In a further configuration, the attachment mechanism at each end of the electronics tray comprises at least two engagement members on opposite sides (e.g., a right side and a left side) of the electronics tray to each be contained within a different securing portion of the electronics rack to secure the electronics tray within the electronics rack. Each engagement member in an embodiment includes an engagement member biasing mechanism to bias the respective engagement member to an extended position such that each respective engagement member is containable within a respective different securing portion of the electronics rack to secure the electronics tray to the electronics rack. Each respective engagement member preferably is moveable to a retracted position where each respective engagement member does not engage the respective different securing portions within the electronics rack. Each engagement member in a further embodiment includes at least one recess to engage at least one projection associated with the electronics tray to guide movement of each respective engagement member relative to the electronics tray, and further each engagement member optionally includes a travel limit mechanism to limit the amount of distance each respective engagement member travels relative to the electronics tray.

In a further embodiment, at least one engagement member includes an integrated group, e.g., an inclined surface, configured to contact corresponding structure in the electronics rack in response to moving the electronics tray to move the at least one engagement member so that the at least one engagement member is not contained in a securing portion in the electronics rack, and in an approach the at least one engagement member comprises an engagement surface that inhibits movement of the electronics tray, e.g., from the respective securing portion, by contacting an engaging surface in the electronics rack. The securing portion in one or more configurations comprises a holding chamber formed by: an engaging surface that interacts with the engagement surface of the at least one engagement member to inhibit movement of the electronics tray, and at least one of an structure group configured to move the at least one engagement member to permit movement of the electronics tray, the structure group consisting of an inclined surface, a rounded surface, rollers, and combinations thereof.

Also disclosed is a method of installing an electronics tray containing a plurality of electronics components in an electronics rack in multiple directions, including in an embodiment from a front end toward a rear end of the electronics rack and from a rear end toward the front end of the electronics rack. The method of installing in one or more approaches includes moving a first attachment mechanism at the front end of the electronics tray to a retracted position wherein the first attachment mechanism is not securable and/or contained within the electronics rack. The method in an embodiment includes moving the electronics tray into an installation position in the electronics rack. In an aspect the method includes moving the first attachment mechanism, in response to the electronics tray being located in the installation position in the electronics rack, to an extended position where the first attachment mechanism is contained within a first securing portion of the electronics rack. The method in an approach further includes moving a second attachment mechanism at the rear end of the electronics tray, in response to the electronics tray being located in the installation position in the electronics rack, to an extended position where the second attachment mechanism is contained within a second different securing portion of the electronics rack.

In an aspect, moving the second attachment mechanism at the rear end of the electronics tray to the retracted position includes moving an interface group, e.g., an inclined surface, of the second attachment mechanism into contact with and relative to a corresponding structure in the electronics rack to move the second attachment mechanism to the retracted position against the biasing force of the second biasing mechanism, and in a further approach moving the interface group of the second attachment mechanism beyond the corresponding structure of the electronics rack so the interface group no longer contacts the corresponding structure of the electronics rack. In one or more approaches, moving the first attachment member of the electronics tray to the retracted position comprises moving an interface group, e.g., an inclined surface, of the first attachment mechanism into contact with and relative to a corresponding structure in the electronics rack to move the first attachment mechanism to the retracted position against the biasing force of the first biasing mechanism and in a further approach moving the interface group of the first attachment mechanism beyond the corresponding structure of the electronics rack so the interface group no longer contacts the corresponding structure of the electronics rack.

A method of removing and/or moving the electronics tray from the installation position and/or from the electronics rack is also disclosed. In one or more embodiments, to remove and or move the electronics rack from the installation position, preferably a user applies a force to move an attachment mechanism at one end of the electronics tray into a retracted position and pulls on the electronics tray so that an attachment mechanism at the other end of the electronics tray retracts and disengages from the installation position in the electronics rack.

The foregoing summary is illustrative only and is not intended to be in any way limiting. In addition to the illustrative aspects, implementations, and features described above, further aspects, implementations, and features will become apparent by reference to the drawings and the following detailed description. In the drawings, like reference numbers indicate identical or functionally similar elements.

### BRIEF DESCRIPTION OF THE DRAWINGS

FIG. 1 illustrates a perspective view of an example embodiment of an electronics rack containing a plurality of electronics trays.

FIG. 2 illustrates a top view of an example embodiment of an electronics tray according to the disclosure.

FIG. 3 illustrates a side view of an example embodiment of an electronics tray according to the disclosure.

FIG. 4 illustrates an expanded view of a portion of the electronics tray from FIG. 3.

FIG. 5 illustrates a top perspective view of the front of an example embodiment of the electronics tray according to the disclosure.

FIG. 6 illustrates an expanded view of the right side of the front of an example embodiment of an electronics tray according to the disclosure.

FIG. 7 illustrates an expanded view of the left side of the front of an example embodiment of an electronics tray according to the disclosure.

FIG. 8 illustrates a schematic diagram of installing from the front of an electronics rack an example embodiment of an electronics tray according to the disclosure.

FIG. 9 illustrates a schematic diagram of an example embodiment of an electronics tray installed in an electronics rack according to the disclosure.

FIG. 10 illustrates a schematic diagram of installing from the rear of an electronics rack an example embodiment of an electronics tray according to the disclosure.

FIG. 11 illustrates a schematic diagram of removing from the rear of an electronics rack an example embodiment of an electronics tray according to the disclosure.

FIG. 12 illustrates a schematic diagram of removing from the front of an electronics rack an example embodiment of an electronics tray according to the disclosure.

### DETAILED DESCRIPTION

### Overview

Racks containing electronic components (referred herein as “electronics racks” or “racks”), such as, for example, servers, networking gear, etc., generally contain multiple electronic trays that are assembled and installed in the electronics racks. The electronics trays contain multiple electronic components, e.g., integrated circuits, hard drives, etc., positioned and attached to one or more printed circuit boards. The electronics trays are generally horizontally arranged substantially as or in a horizontal plane and are generally moved horizontally, e.g., slide, into the electronics racks and secured in and/or to the electronics racks. There usually are one or more guide surfaces on the chassis of the electronics rack to guide installation of the electronic trays in the electronics racks, and in embodiments the electronics trays include an engagement or locking mechanism to secure the electronics tray to the electronics rack.

Described herein is a system, mechanism, product and/or method for permitting and facilitating multidirectional installation, removal, containment, and/or securement of electronics trays, which generally contain multiple electronic components arranged in planar fashion on one or more printed circuit boards, in an electronics rack. The disclosed system, mechanism, product, and/or method in an embodiment includes a first attachment mechanism at a first or front end of the electronics tray for engaging and/or securing the electronics tray in the electronics rack and a second attachment mechanism at a second or rear end (e.g., opposite from the first end) of the electronics tray for engaging and/or securing the electronics tray in the electronics rack. The first and second attachment mechanisms permit the electronics tray to be moved, installed, and/or removed in/from the electronics racks in multiple directions, preferably at least two directions, for example by horizontally moving (e.g., sliding) the electronics tray into position and securing and/or containing the electronics tray in the electronics rack.

In an arrangement, at least one of the first or second attachment mechanisms, preferably both the first and second attachment mechanisms, include a respective first, second, and/or both a first and second biasing mechanism for applying a biasing force to bias and/or move the respective first, second, and/or both the first and second attachment mechanisms to engage, rest within and/or be contained within a portion of the electronics rack to secure and/or connect the electronics tray within and/or to the electronics rack. In a configuration, each of the first, second, and/or both first and second biasing mechanisms includes a spring element, preferably arranged between a portion of the electronics tray and the respective first and/or second attachment mechanism.

The first attachment mechanism in an embodiment includes at least two engagement members (e.g., first and second engagement members of the first attachment mechanism) arranged on opposite sides (e.g., left side and right side) of the front end of the electronics tray and each of the at least two engagement members of the first attachment mechanism are biased to extend outward beyond the periphery or perimeter of the electronics tray to facilitate and/or permit the respective engagement member to engage, be secured within, be contained within, and/or connected to the, or a portion of the, electronics rack. The second attachment mechanism in an embodiment also includes at least two engagement members (e.g., first and second engagement members of the second attachment mechanism) arranged on opposite sides (e.g., left side and right side) of the back or rear end of the electronics tray and each of the at least two engagement members of the second attachment mechanism are biased to extend outward beyond the periphery or perimeter of the electronics tray to facilitate and/or permit the respective engagement member to engage, be secure within, be contained within, and/or connect to the, or a portion of the, electronics rack.

In one or more arrangements, the electronics tray is configured to be installed and removed by moving, preferably horizontally sliding, the electronics tray in a first direction and/or an opposite second direction and the first and second attachment mechanisms, including in one or more embodiments that at least two engagement members of the first attachment mechanism and the at least two engagement members of the second attachment mechanism, are configured to move a direction different than the first and opposite second direction, preferably in directions substantially perpendicular to or perpendicular to the first and opposite second directions.

Further described is one or more example methods of installing and/or removing the electronic tray from an electronics rack. In an embodiment, the first attachment mechanism is moved to a second (e.g., retracted) position against a force of a first attachment biasing mechanism so that the first attachment mechanism does not extend beyond the periphery of the electronics tray and/or does not engage, contact, and/or is not secured or contained within the, or a portion of the electronics rack (e.g., a holding chamber) and the electronics tray can be moved (e.g. pulled by a user) toward and be removed from the front end of the electronics rack. In an embodiment, a first engagement member of the first attachment mechanism is moved to a second (e.g., retracted) position against a first force of a first engagement member biasing mechanism and a second engagement member of the first attachment mechanism is moved to a second (e.g., retracted) position against a second force of a second engagement biasing mechanism so that the first engagement member and the second engagement member do not extend beyond the periphery of the electronics tray and/or does not engage, contact, and/or is not secured or contained within the, or a portion of the, electronics rack (e.g., a holding chamber) and the electronics tray can be moved (e.g., pulled by a user) toward and out the front end of the electronics rack.

In one or more arrangements, in response to the electronics tray being moved toward and out the front end of the electronics rack, an interface group, e.g., an inclined surface, of the second attachment mechanism engages and/or contacts one or more corresponding and opposite direction facing structures, e.g., inclined surfaces, associated with the electronics rack so that the second attachment mechanism moves against the force of the second attachment biasing mechanism and does not engage and/or contact and is not secured or contained within the, or a portion of the, electronics rack (e.g., a holding chamber) to facilitate and permit sliding movement of the electronics tray toward and out the front end of the electronics rack.

In one or more approaches, in response to the electronics tray being moved toward and removed from the front end of the electronics rack, a third interface group, e.g., a third inclined surface, of a third engagement member of the second attachment mechanism engages and/or contacts a corresponding and opposite direction facing sixth structure, e.g., a sixth inclined surface, associated with the electronics rack so that the third engagement member of the second attachment mechanism moves against the force of the third engagement member biasing mechanism of the second attachment mechanism and the third engagement member does not engage and/or contact and is not secured or contained within the, or a portion of the, electronics rack (e.g., a holding chamber) to facilitate and permit movement (e.g., horizontal sliding) of the electronics tray toward and out the front end of the electronics rack. In one or more approaches, in response to the electronics tray being moved toward and removed from the front end of the electronics rack, a fourth interface group, e.g., a fourth inclined surface, of a fourth engagement member of the second attachment mechanism engages and/or contacts a corresponding and opposite direction facing eight structure, e.g., an eighth inclined surface, associated with the electronics rack so that the fourth engagement member of the second attachment mechanism moves against the force of the fourth engagement member biasing mechanism of the second attachment mechanism and the fourth engagement member does not engage and/or contact and is not secured or contained within the, or a portion of the, electronics rack (e.g., a holding chamber) to facilitate and permit movement (e.g., horizontal sliding) of the electronics tray toward and out the front end of the electronics rack.

In an embodiment, the second attachment mechanism is moved to a second (e.g., retracted) position against a force of a second attachment biasing mechanism so that the second attachment mechanism does not extend beyond the periphery of the electronics tray and/or does not engage, contact, and/or is not secured or contained within the, or a portion of the, electronics rack (e.g., a holding chamber) and the electronics tray can be moved (e.g. pulled by a user) toward and be removed from the rear end of the electronics rack. In an embodiment, a third engagement member of the third attachment mechanism is moved to a second (e.g., retracted) position against a third force of a third engagement member biasing mechanism and a fourth engagement member of the second attachment mechanism is moved to a second (e.g., retracted) position against a fourth force of a fourth engagement biasing mechanism so that the respective third engagement member and fourth engagement member do not extend beyond the periphery of the electronics tray and/or does not engage, contact, and/or is not secured or contained within the, or a portion of the, electronics rack (e.g., a holding chamber) and the electronics tray can be moved (e.g., pulled by a user) toward and out the rear end of the electronics rack.

In one or more arrangements, in response to the electronics tray being moved toward and out the rear end of the electronics rack, an interface group, e.g., an inclined surface, of the first attachment mechanism engages and/or contacts one or more corresponding and opposite direction facing structures, e.g., inclined surfaces, associated with the electronics rack so that the first attachment mechanism moves against the force of the first attachment biasing mechanism and does not engage and/or contact and is not secured or contained within the, or a portion of the, electronics rack (e.g., a holding chamber) to facilitate and permit sliding movement of the electronics tray toward and out the rear end of the electronics rack.

In one or more approaches, in response to the electronics tray being moved toward and removed from the rear end of the electronics rack, a first interface group, e.g., a first inclined surface, of a first engagement member of the first attachment mechanism engages and/or contacts a corresponding and opposite direction facing second structure, e.g., a second inclined surface, associated with the electronics rack so that the first engagement member of the first attachment mechanism moves against the force of the first engagement member biasing mechanism of the first attachment mechanism and the first engagement member does not engage and/or contact and is not secured or contained within the, or a portion of the, electronics rack (e.g., a holding chamber) to facilitate and permit movement (e.g., horizontal sliding) of the electronics tray toward and out the rear end of the electronics rack. In one or more approaches, in response to the electronics tray being moved toward and removed from the rear end of the electronics rack, a second interface group, e.g., a second inclined surface, of a second engagement member of the first attachment mechanism engages and/or contacts a corresponding and opposite direction facing fourth structure, e.g., a fourth inclined surface, associated with the electronics rack so that the second engagement member of the first attachment mechanism moves against the force of the second engagement member biasing mechanism of the first attachment mechanism and the second engagement member does not engage and/or contact and is not secured or contained within the, or a portion of the, electronics rack (e.g., a holding chamber) to facilitate and permit movement (e.g., horizontal sliding) of the electronics tray toward and out the rear end of the electronics rack.

In the following description, numerous specific details are set forth, such as particular structures, components, materials, dimensions, processing steps and techniques, in order to provide an understanding of the various implementations of the present application. However, it will be appreciated by one of ordinary skill in the art that the various implementations of the present application may be practiced without these specific details. In other instances, well-known structures or processing steps have not been described in detail in order to avoid obscuring the present application.

### Example Environment

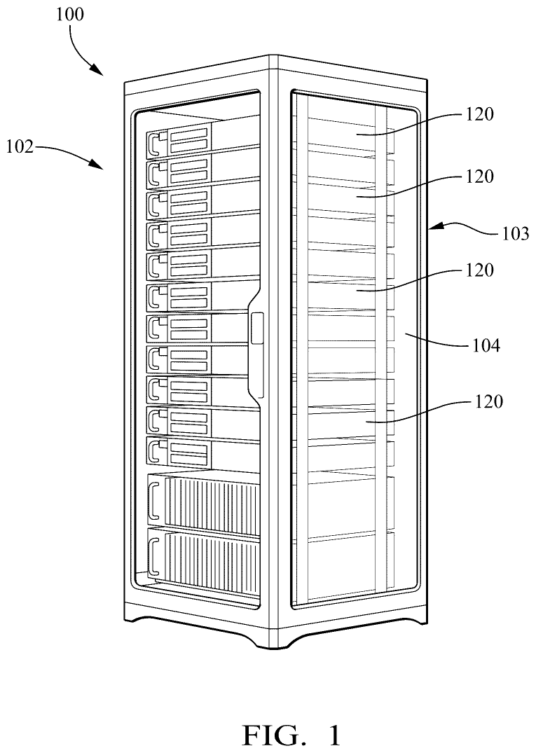

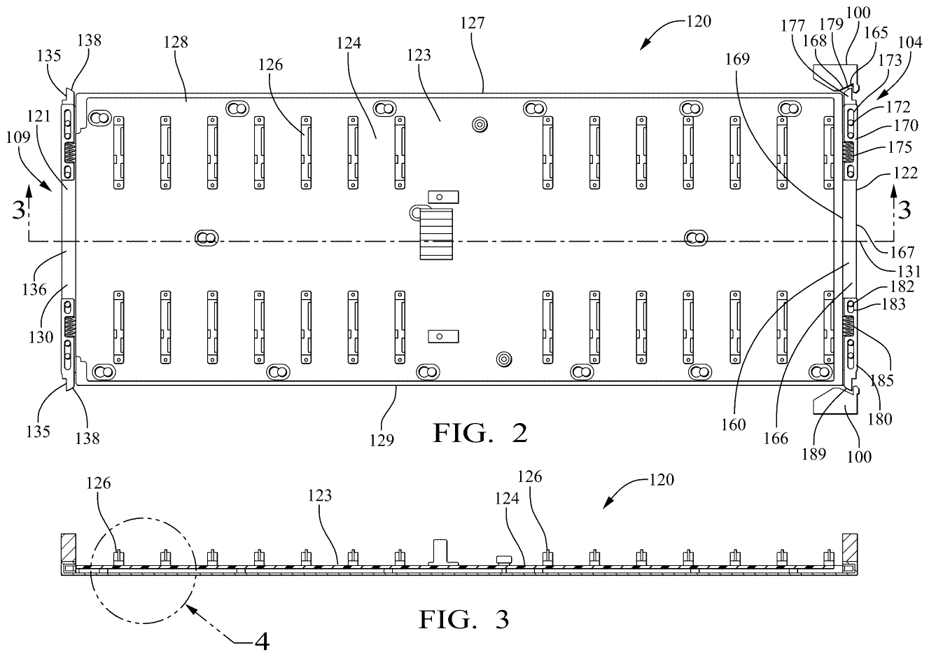

FIG. 1 illustrates an example environment of multiple electronics trays 120 arranged, positioned within, and/or installed in an electronics rack 100, for example a server rack. The electronics rack includes a front 102 (also referred to as front end 102) and a rear 103 (opposite the front 102), as well as a right side 104 and an opposite left side 109 (not shown). An electronics tray 120, shown in FIG. 2, generally contains multiple electronic components 123 arranged and/or connected in one or more planes, preferably a single plane, where the electronics tray 120 is configured to be positioned within and/or installed in the electronics rack 100. In one or more example embodiments, an electronics tray 120 includes multiple electronic components 123 arranged and electrically connected on one or more printed circuit boards 124 connected and/or secured to a tray chassis 125. In an example embodiment, the electronics tray 120 can be configured as a hard-drive back plane (HDBP) or hard-drive backplate (HDBP) tray, although other configurations for and/or other electronic and electrical components arranged on electronics tray 120 are contemplated. The electronics tray 120 can be slide into and out of electronics servers, canisters, drawers, or other subassemblies of the electronics rack and the disclosure is not limited by the subassemblies, housing, and/or environment of the electronics rack into which the electronics tray is secured and/or installed.

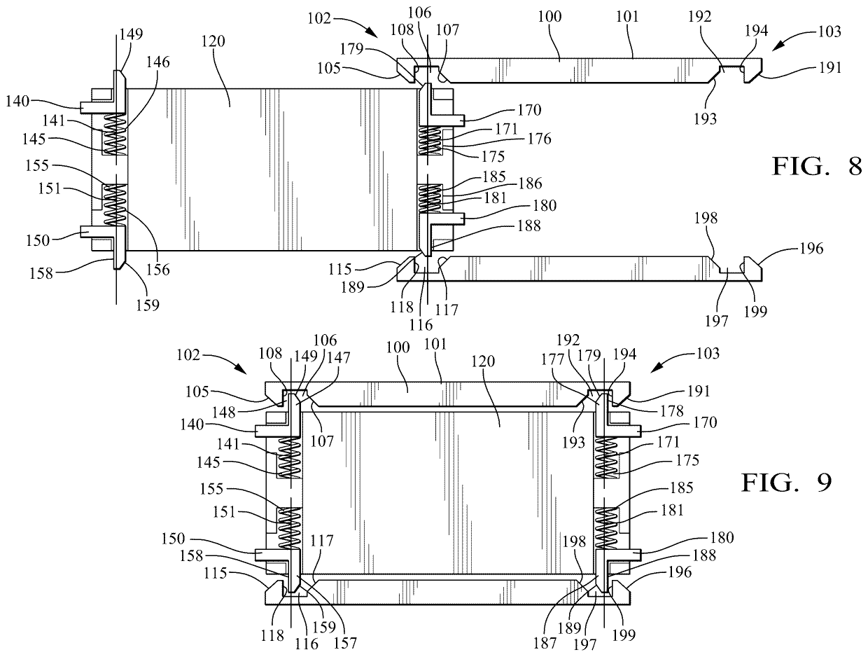

The electronics rack 100 includes in one or more configurations one or more guide surfaces 101 (See FIGS. 8-12) to support and/or guide the electronics tray 120 into position in the electronics rack 100 and further includes in one or more arrangements one or more engagement and/or securing surfaces discussed in more detail below for engaging, attaching, securing, and/or containing the electronics tray 120 to and/or within the electronics rack 100. Electronics rack 100 in one or more approaches also includes one or more surfaces (e.g., inclined and perpendicular surfaces) described in more detail to interact with one or more surfaces (e.g., inclined and perpendicular) of the electronics tray 120 as will be discussed in more detail below.

### Example Implementation

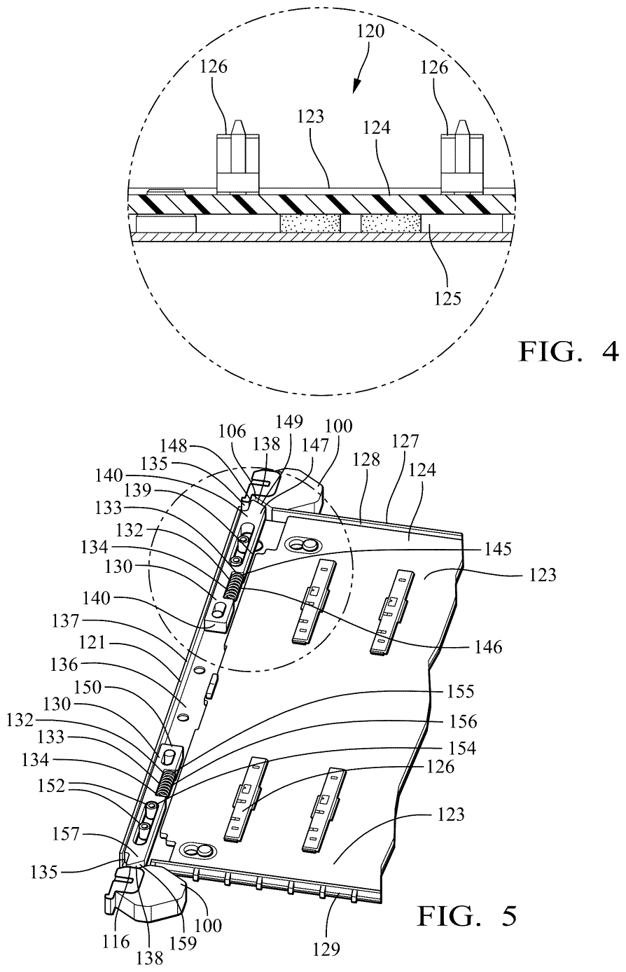

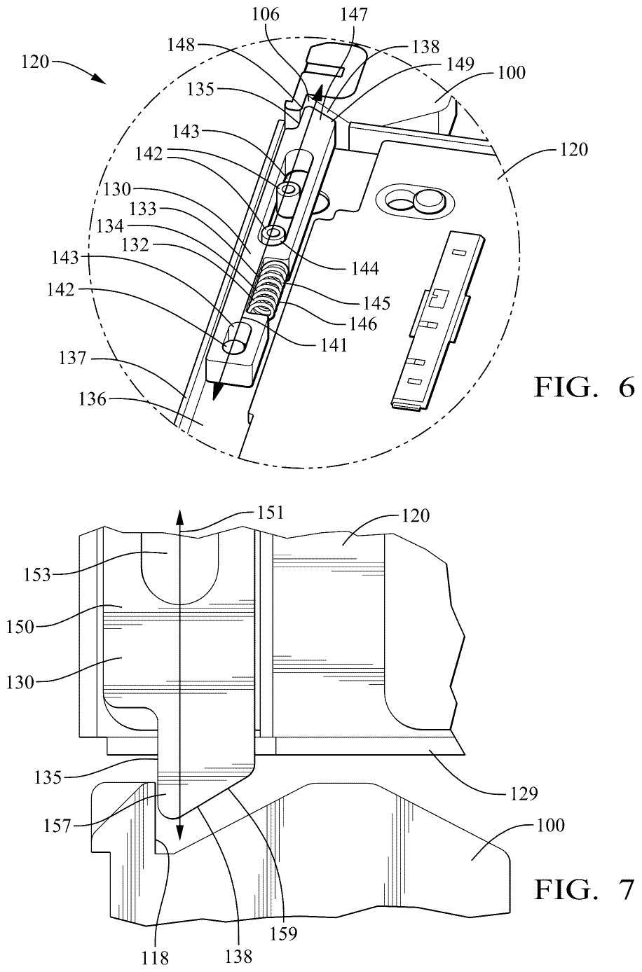

FIGS. 2-7 illustrate an example implementation of an electronics tray 120 according to an example embodiment. As seen in FIGS. 2-7, in an embodiment, tray 120 includes a printed circuit board 124, containing multiple electronic components 123, e.g., integrated circuits, hard drives, etc., which is secured to and/or attached to a tray chassis 125. One or more connectors 126, e.g., electrical connectors, are included in an example embodiment of electronics tray 120.

Tray 120 has a first or front end 121 and a second or rear end 122. Tray 120 also includes a right side 128 and a left side 129. Tray 120 includes a first attachment mechanism 130 arranged, positioned, associated with, and/or located at first or front end 121 and a second attachment mechanism 160 arranged, positioned, associated with and/or located at second or rear end 122 of tray 120. Tray 120 can be installed and/or removed by moving, e.g., sliding, tray 120 at least bi-directionally in two different directions. For example, in one or more embodiments electronics tray 120 can be installed and/or removed by moving electronics tray 120 into or out of a front 102 of the electronics rack 100 and electronics tray 120 can be installed and/or removed by moving, e.g., sliding, tray 120 into or out of a rear 103 of the electronics rack 100 in a direction opposite from the direction when installing and/or removing the electronics tray 120 from front 102 of the electronics rack 100. Alternatively, and/or additionally, in one or more configurations the electronics tray 120 can be installed and/or removed by moving the electronics tray 120 into or out of the right side 104 of the electronics rack 100 and electronics tray 120 can be installed and/or removed by moving the electronics tray 120 into and out of the left side 109 of the electronics rack 100.

First attachment mechanism 130 and second attachment mechanism 160 attaches and/or secures electronics tray 120 to, and/or is contained within, electronics rack 100 during installation of electronics tray 120 within electronics rack 100. The first attachment mechanism 130 and the second attachment mechanism 160 in one or more embodiments are attached and/or secured to the electronics tray 120. The first attachment mechanism 130 and the second attachment mechanism 160 in one or more configurations are moveable with respect to the electronics tray 120. In one or more configurations, first attachment mechanism 130 and/or second attachment mechanism is secured and/or contained within one or more holding chambers formed within electronics rack 100. First attachment mechanism 130 is associated with a first end (e.g., front end 121) of electronics tray 120 and configured similar to second attachment mechanism 160 associated with a second opposite end (e.g., rear end 122) of electronics tray 120, except first attachment mechanism 130 is configured to face a different direction than second attachment mechanism 160. First attachment mechanism 130 and second attachment mechanism 160 in one or more configurations move in directions different than electronics tray 120 moves during the process of installing and/or removing electronics tray 120 from the electronics rack 100. In one or more arrangements, first attachment mechanism 130 and second attachment mechanism 160 move substantially perpendicular to or perpendicular to longitudinal axis 131 of electronics tray 120, and in an embodiment move substantially perpendicular to or perpendicular to the direction that electronics tray 120 moves while installing and/or removing electronics tray 120 from the electronics rack 100.

First attachment mechanism 130 at front end 121 of electronics tray 120 in an embodiment includes at least a first attachment mechanism biasing mechanism 132 that applies a force to urge or bias the first attachment mechanism 130 beyond the right side 128 and/or left side 129 (e.g., beyond the periphery 127) of electronics tray 120 so that the first attachment mechanism 130 contacts, attaches to, and/or secures the electronics tray 120 to the electronics rack 100, for example by being contained and/or secured within a holding chamber formed and/or configured in the electronics rack 100 that resists movement of the electronics tray 120. Second attachment mechanism 160 at the rear end 122 of the electronics tray 120 in an embodiment includes at least a second attachment mechanism biasing mechanism 162 that applies a force to urge or bias the second attachment mechanism 160 beyond the right side 128 and/or left side 129 (e.g., beyond the periphery 127) of electronics tray 120 so that the second attachment mechanism 160 contacts, attaches to, and/or secures the electronics tray 120 to the electronics rack 100, for example by being contained and/or secured within a holding chamber formed and/or configured within electronics rack 100 that resists movement of the electronics tray 120.

In an embodiment, the first attachment mechanism biasing mechanism 132 includes a first biasing element 133, which could be one or more helical and/or compression springs 134. First biasing element 133 and/or one or more compression/helical springs 134 can be positioned, configured, and/or located between a portion of the electronics tray 120 and the first attachment mechanism 130. The first attachment mechanism 130 in a configuration includes one or more engagement surfaces 135 for contacting and/or engaging a corresponding portion of the electronics rack 100 to inhibit, impede, block, and/or prevent movement, e.g., sliding, of the electronics tray 120 in the direction of the front 102 of the electronics rack 100.

In an embodiment, the second attachment mechanism biasing mechanism 162 includes a second biasing element 163, which could be a helical and/or compression spring 164. Second biasing element 163 and/or compression/helical spring 134 can be positioned, configured, and/or located between a portion of the electronics tray 120 and the second attachment mechanism 160. The second attachment mechanism 160 in a configuration includes a second engagement surface 165 for contacting and/or engaging a corresponding portion of the electronics rack 100 to inhibit, impede, block, and/or prevent movement, e.g., sliding, of the electronics tray 120 in the direction of the rear 103 of the electronics rack 100.

In a further embodiment, the first attachment mechanism 130 includes a first interface group 138, e.g., a first inclined surface 138, to interact with surfaces associated with and/or included in the electronics rack 100 so that in response to rearward movement of the electronics tray 120 relative to the electronics rack 100 in the direction of rear 103 of the electronics rack 100 the first attachment mechanism 130 moves in a direction against the force applied by the first attachment mechanism biasing mechanism 132, and preferably to a retracted position so that first attachment mechanism 130 does not extend beyond the periphery 127 of the electronics tray 120 and preferably does not engage and/or contact the corresponding portion of the electronics rack 100 that inhibits, impedes, blocks, and/or prevents movement of the electronics tray 120 and in an embodiment so that first attachment mechanism 130 does not extend into or is not contained within a holding chamber formed in and/or configured within the electronics rack 100.

In a further embodiment, the second attachment mechanism 160 includes a second interface group 168, e.g., a second inclined surface 168 to interact with surfaces associated with and/or included in the electronics rack 100 so that in response to frontward movement of the electronics tray 120 relative to the electronics rack 100 in the direction of front 102 of the electronics rack 100 the second attachment mechanism 160 moves in a direction against the force applied by the second attachment mechanism biasing mechanism 162, and preferably to a retracted position so that second attachment mechanism 160 does not extend beyond the periphery 127 of the electronics tray 120 and preferably does not engage and/or contact the corresponding portion of the electronics rack 100 that inhibits, impedes, blocks, and/or prevents movement of the electronics tray 120 and in an embodiment so that second attachment mechanism 160 does not extend into or is not contained within a holding chamber formed in and/or configured within the electronics rack 100.

In one or more embodiments, the first attachment mechanism 130 on the front end 121 of the electronics tray 120 includes at least two moveable engagement members, e.g., first and second engagement members 140, 150. First engagement member 140 is similar to second engagement member 150. First engagement member 140 is secured and/or attached to right side 128 of electronics tray 120 and is moveable to extend beyond the periphery 127 of the right side 128 of electronics tray 120 to engage, contact, and/or secure electronics tray 120 to the electronics rack 100, for example by containing at least a portion of first engagement member 140 in a first holding chamber 106. Second engagement member 150 is secured and/or attached to left side 129 of the electronics tray 120 and is moveable to extend beyond the periphery 127 of the left side 129 of electronics tray 120 to engage, contact, and/or secure electronics tray 120 to the electronics rack 100, for example by containing at least a portion of second engagement member 150 in a second holding chamber 116.

In an embodiment, electronics tray 120 is configured so that it can move multi-directionally (e.g., at least bi-directionally) to install and/or remove electronics tray 120 from electronics rack 100. For example, the electronics tray 120 in an embodiment is configured to be installed and/or removed from the front 102 and/or the rear 103 of the electronics rack 100, and/or additionally and/or alternatively can be removed from the right side 104 and/or the left side 109 of the electronics rack 100. For example, the electronics tray 120 in an embodiment is contained within a server where the server is installed and/or removed from the front 102 or rear 103 of the electronics rack 100 to obtain access to the electronics tray 120, and the electronics tray 120 is installed and/or removed from the right side and/or left side of the server such that the electronics tray is removed from the right side 104 and/or the left side 109 of the electronics rack 100.

The electronics tray 120 moves, preferably substantially horizontally, in and/or along the direction of its longitudinal axis 131 during installation and/or removal. First and second engagement members 140, 150 are configured to move relative to electronics tray 120 and preferably move in a direction that is different than the movement of electronics tray 120 during installation and/or removal from the electronics rack 100. In one or more embodiments the first and second engagement members 140, 150 move (e.g., slide) in the same plane as the electronics tray and in a direction that is perpendicular to, or substantially perpendicular to, the longitudinal axis 131 of electronics tray 120.

The electronics tray 120 in one or more configurations includes one or more channels, and/or guide surfaces and structures to guide and/or contain movement of the first and second engagement members 140, 150. In an embodiment, electronics tray 120 includes an end wall 137 and a secondary wall 139 that forms a channel 136 to guide movement of and contain first engagement member 140. Similarly, in an embodiment, end wall 137 and secondary wall 139 forms a channel 136 to guide movement of and contain second engagement member 150. It can be appreciated that the guide structures and/or channel 136 guiding and/or containing movement of first and second engagement members 140, 150 can be formed and/or configured with different components, in different locations, and/or in different shapes than illustrated in the figures.

Additionally, and/or alternatively, electronics tray 120 includes one or more projections 142 that contact, engage, and/or interact with one or more recesses 143 on first engagement member 140 to guide and/or contain movement of first engagement member 140 relative to electronics tray 120. In one or more embodiments, the one or more projections 142 contact, engage, and/or interact with recesses 143 on first engagement member 140 to limit the extent and/or amount of movement or travel of first engagement member 140. Recesses 143 in an embodiment are slots which are oversized compared to the projections 142 to permit first engagement member 140 to move relative to projections 142. That is, in one or more embodiments, the configuration of the one or more projections 142 and recesses 143 form a first travel limit mechanism 144 that can limit the amount of travel that first engagement member 140 extends beyond the periphery 127 of the electronics tray 120 and the amount of travel of first engagement member 140.

Additionally, and/or alternatively, electronics tray 120 includes one or more projections 152 that contact, engage, and/or interact with one or more recesses 153 on second engagement member 150 to guide and/or contain movement of second engagement member 150 relative to electronics tray 120. In one or more embodiments, the one or more projections 152 contact, engage, and/or interact with recesses 153 on second engagement member 150 to limit the extent and/or amount of movement or travel of second engagement member 150. Recesses 153 in an embodiment are slots which are oversized compared to the projections 152 to permit second engagement member 150 to move relative to projections 152. That is, in one or more embodiments, the configuration of the one or more projections 152 and recesses 153 form a second travel limit mechanism 154 that can limit the amount of travel that second engagement member 150 extends beyond the periphery 127 of the electronics tray 120 and the amount of travel of second engagement member 150.

In one or more arrangements, a first engagement member biasing mechanism 145 is positioned and/or arranged to apply a biasing force to first engagement member 140 to bias and/or move first engagement member 140 beyond the periphery 127 of the right side 128 of the electronics tray 120 to engage, contact, and/or be secured to the electronics tray 120, for example to be contained within a holding chamber formed and/or configured in the electronics rack 100. In an embodiment, first engagement member biasing mechanism 145 includes a spring element 146, for example a compression and/or helical spring. Spring element 146 is positioned and/or arranged between the electronics tray 120 and the first engagement member 140, for example a portion of first engagement member 140, to apply a force to the first engagement member 140 to move and/or bias the first engagement member 140 to extend beyond the periphery 127 of the electronics tray 120 and into a position (e.g., within a holding chamber formed and/or configured in the electronics rack 100) to secure the electronics tray 120 in position within the electronics rack 100. Movement of first engagement member 140 in one or more approaches is limited by one or more of projections 142 contacting and/or engaging the ends of recesses 143.

In one or more arrangements, a second engagement member biasing mechanism 155 is positioned and/or arranged to apply a biasing force to second engagement member 150 to bias and/or move second engagement member 150 beyond the periphery 127 of the left side 129 of the electronics tray 120 to engage, contact, and/or be secured to the electronics tray 120, for example to be contained within a holding chamber formed and/or configured within the electronics rack 100. In an embodiment, second engagement member biasing mechanism 155 includes a spring element 156, for example a compression and/or helical spring. Spring element 156 is positioned and/or arranged between the electronics tray 120 and the second engagement member 150, for example a portion of second engagement member 150, to apply a force to the second engagement member 150 to move and/or bias the second engagement member 150 to extend beyond the periphery 127 of the electronics tray 120 and into a position (e.g., within a holding chamber formed and/or configured in the electronics rack 100) to secure the electronics tray 120 in position within the electronics rack 100. Movement of second engagement member 150 in one or more approaches is limited by one or more of projections 152 contacting and/or engaging the ends of recesses 153.

First engagement member 140 and second engagement member 150 in one or more configurations each include one or more user interface surfaces for a user to apply a force to move respective first engagement member 140 and second engagement member 150. The user interface surfaces facilitate a user applying force to respective first and/or second engagement members 140, 150 to move respective first and/or second engagement members 140, 150 against the biasing force provided by respective first engagement member biasing mechanism 145 and the second engagement member biasing mechanism 155.

First projecting end 147 of first engagement member 140 in an embodiment has a first engagement surface 148 and an interface group 149, e.g., an inclined surface 149. That is, first projecting end 147, which has at least a portion that is configured and arranged to extend beyond the periphery 127 of the right side 128 of the electronics tray 120, in response to first engagement member 140 being in an extension position, has a first engagement surface 148 that is configured to engage and/or contact a corresponding first engaging surface 108 of the electronics tray 120 to inhibit, impede, and/or prevent movement and/or removal of electronics tray 120 within the electronics rack 100.

With first engagement member 140 in an extension position, removing electronics tray 120 from electronics rack 100 is inhibited, impeded and/or prevented as first engagement surface 148 contacts and engages a portion, e.g., corresponding engaging surface 108, of electronics rack 100. In an embodiment, first engagement surface 148 is substantially perpendicular to the movement of electronics tray 120 during installation and/or removal from electronics rack 100. That is, first engagement surface 148 is configured to be perpendicular to, or substantially perpendicular to, the longitudinal axis 131 of electronics tray 120 and in an embodiment is aligned with longitudinal axis 141 of first engagement member 140. In one or more approaches, first engagement surface 148 is aligned in the direction of movement of first engagement member 140 relative to electronics tray 120. With first engagement member 140 in a retracted position, first engagement surface 148 of electronics tray 120 is moved to a position such that engagement surface 148 does not and will not contact or engage a portion of electronics rack 100 facilitating and/or permitting movement and/or removal of electronics tray 120 from electronics rack 100.

Second engagement member 150 is similar to the configuration of first engagement member 140 and is positioned within electronics tray 120 and operates in a manner similar to first engagement member 140, but second engagement member 150 is positioned on the left side 129 of electronics tray 120. Second engagement member 150 in an embodiment has a second projecting end 157 that in an arrangement has a second engagement surface 158 and a second interface group 159, e.g., a second inclined surface 159. That is, second projecting end 157 is configured and arranged to extend beyond the periphery 127 of the left side 129 of the electronics tray 120, in response to second engagement member 150 being in an extension position, has a second engagement surface 158 that is configured to engage and/or contact a corresponding second engaging surface 118 of the electronics tray 120 to inhibit, impede, and/or prevent movement and/or removal of electronics tray 120 within the electronics rack 100.

With second engagement member 150 in an extension position, removing electronics tray 120 from electronics rack 100 is inhibited, impeded and/or prevented as second engagement surface 158 contacts and engages a portion, e.g., corresponding second engaging surface 118, of electronics rack 100. In an embodiment, second engagement surface 158 is substantially perpendicular to the movement of electronics tray 120 during installation and/or removal from electronics rack 100. That is, second engagement surface 158 is configured to be perpendicular to, or substantially perpendicular to, the longitudinal axis 131 of electronics tray 120 and in an embodiment is aligned with longitudinal axis 151 of second engagement member 150. In one or more approaches, second engagement surface 158 is aligned in the direction of movement of second engagement member 150 relative to electronics tray 120. With second engagement member 150 in a retracted position, second engagement surface 158 of electronics tray 120 is moved to a position such that engagement surface 158 does not and will not contact or engage a portion of electronics rack 100 facilitating and/or permitting movement and/or removal of electronics tray 120 from electronics rack 100.

While first and second engagement surfaces 148, 158 have been described and illustrated as being perpendicular to longitudinal axis 141, 151 of first and second engagement members 140, 150 it can be appreciated that first and second engagement surfaces 148, 158 can be inclined or sloped (e.g., not perpendicular with respect to longitudinal axis 141, 151) but preferably are shaped and configured to engage and/or contact structure in electronics rack 100 to inhibit, impede, and/or prevent movement of electronic tray 120 until a user applied force moves the first and second engagement members 140, 150 in a retraction direction so that first and second engagement surfaces 148, 158 no longer contact and/or engage blocking structures in electronics rack 100.

First engagement member 140 in one or more embodiments has first interface group 149 which is configured to engage a corresponding structure on the electronics rack 100 to move and/or retract first engagement member 140 in response to rearward movement of electronics tray 120 relative to electronics rack 100. That is, in one or more arrangements, as electronics tray 120 is moved rearward toward the rear 103 of electronics rack 100, first interface group 149 contacts structure in the electronics rack 100 such that in response to further rearward movement of electronics tray 120 in electronics rack 100, first engagement member 140 retracts, e.g., moves in channel 136 perpendicular (or substantially perpendicular) to the longitudinal axis 131 of electronics tray 120, such that first engagement member 140 can move past (e.g., rearward of) the electronics rack structure. By applying a force (e.g., a user applied force) to electronics tray 120 in a rearward direction and/or by moving electronics tray 120 in a rearward direction, first interface group 149, e.g., first inclined surface 149, contacts structure in electronics rack 100, which moves first engagement member 140 against the force/resistance applied by first engagement member biasing mechanism 145, e.g., against the force/resistance from spring element 146. First interface group 149 is illustrated as an inclined surface 149, but it can be appreciated that first interface group 149 can include one or more of inclined surfaces, rounded surfaces, and/or rollers.

Second engagement member 150 in one or more embodiments has second interface group 159 which is configured to engage a corresponding structure on the electronics rack 100 to move and/or retract second engagement member 150 in response to rearward movement of electronics tray 120 relative to electronics rack 100. That is, as electronics tray 120 is moved rearward toward the rear 103 of electronics rack 100, second interface group 159 contacts structure in the electronics rack 100 such that in response to further rearward movement of electronics tray 120 in electronics rack 100, second engagement member 150 retracts, e.g., moves in channel 136 perpendicular to the longitudinal axis 131 of electronics tray 120, such that second engagement member 150 can move past the electronics rack structure. By applying a force (e.g., a user applied force) to electronics tray 120 in a rearward direction and/or by moving electronics tray 120 in a rearward direction, second interface group 159, e.g., second inclined surface 159, contacts structure in electronics rack 100, which moves second engagement member 150 against the force applied by second engagement member biasing mechanism 155, e.g., against the force from spring element 156. Second interface group 159 is illustrated as an inclined surface 159, but it can be appreciated that second interface group 159 can include one or more of inclined surfaces, rounded surfaces, and/or rollers.

It can be appreciated that the interface groups 149, 159 can be varied, e.g., the slope of the inclined surfaces 149, 159 can be varied, as can the structure of the electronics rack 100 that contacts, engages, and/or moves first and second engagement members 140, 150 (e.g., projecting ends 147, 158), and the biasing forces (e.g., the spring constants of spring elements 146, 156) and configurations of the first and second engagement member biasing mechanisms 145, 155 can also be varied to adjust and configure the force necessary to move and/or slide first and second engagement members 140, 150, and accordingly the force to move electronics tray 120 toward the rear 103 of the electronics rack 100. The inclined surfaces 149, 159 preferably have an incline angle between about 30-60 degrees with respect to the side (e.g., the right side 128 or the left side 129) of the electronics tray 120, more preferable between about 40-50 degrees, for example about 45 degrees, although other incline angles for inclined surfaces 149, 159 that are less than 30 degrees and more than 60 degrees are contemplated. It can be appreciated that rollers, curved or rounded surfaces, and/or other structures can be implemented to contact and engage structure in the electronics rack 100, other than inclined surfaces 149, 159, to move and/or retract first and second engagement members 140, 150.

In one or more embodiments, the second attachment mechanism 160 on the rear end 122 of the electronics tray 120 includes at least two moveable engagement members, e.g., third and fourth engagement members 170, 180. Third engagement member 170 is similar to fourth engagement member 180, and third and fourth engagement members 170, 180 are similar to first and second engagement members 130, 140 (e.g., the engaging and inclined surfaces are reversed). Third engagement member 170 is secured and/or attached to right side 128 of electronics tray 120 and is moveable to extend beyond the periphery 127 of the right side 128 of electronics tray 120 to engage, contact, and/or secure electronics tray 120 to the electronics rack 100, for example by containing at least a portion of third engagement member 170 in a third holding chamber 192. Fourth engagement member 180 is secured and/or attached to left side 129 of the electronics tray 120 and is moveable to extend beyond the periphery 127 of the left side 129 of electronics tray 120 to engage, contact, and/or secure electronics tray 120 to the electronics rack 100, for example by containing at least a portion of fourth engagement member 180 in a fourth holding chamber 197.

Electronic tray 120 can be installed and/or removed at least bi-directionally, e.g., from front 102 to rear 103, or vice versa. The electronics tray 120 moves, preferably substantially horizontally, in and along the direction of its longitudinal axis 131 during installation and/or removal. Third and fourth engagement members 170, 180 are configured to move relative to electronics tray 120 and preferably move in a direction that is different than the movement of electronics tray 120 during installation and/or removal from the electronics rack 100. In one or more embodiments the third and fourth engagement members 170, 180 move (e.g., slide) in the same plane as the electronics tray 120 and in a direction that is perpendicular to, or substantially perpendicular to, the longitudinal axis 131 of electronics tray 120.

The electronics tray 120 in one or more configurations includes one or more channels, and/or guide surfaces and structures, to guide and/or contain movement of the third and fourth engagement members 170, 180. In an embodiment, electronics tray 120 includes an end wall 167 and a secondary wall 169 that forms a second channel 166 to guide movement of and contain third engagement member 170. Similarly, in an embodiment, end wall 167 and secondary wall 169 forms second channel 166 to guide movement of and contain fourth engagement member 180. It can be appreciated that the guide structures and/or channel 166 can be formed and/or configured with different components, in different locations, and/or in different shapes than illustrated in the figures.

Additionally, and/or alternatively, electronics tray 120 in one or more embodiments includes one or more projections 172 that contact, engage, and/or interact with one or more recesses 173 on third engagement member 170 to guide and/or contain movement of third engagement member 170 relative to electronics tray 120. In one or more embodiments, the one or more projections 172 contact, engage, and/or interact with recesses 173 on third engagement member 170 to limit the extent and/or amount of movement or travel of third engagement member 170. Recesses 173 in an embodiment are slots which are oversized compared to the projections 172 to permit third engagement member 170 to move relative to projections 172. That is, in one or more embodiments, the configuration of the one or more projections 172 and recesses 173 for a third travel limit mechanism 174 that can limit the amount of travel of third engagement member 170.

Additionally, and/or alternatively, electronics tray 120 includes one or more projections 182 that contact, engage, and/or interact with one or more recesses 183 on fourth engagement member 180 to guide and/or contain movement of fourth engagement member 180 relative to electronics tray 120. In one or more embodiments, the one or more projections 182 contact, engage, and/or interact with recesses 183 on fourth engagement member 180 to limit the extent and/or amount of movement or travel of fourth engagement member 180. Recesses 183 in an embodiment are slots which are oversized compared to the projections 182 to permit fourth engagement member 180 to move relative to projections 182. That is, in one or more embodiments, the configuration of the one or more projections 182 and recesses 183 for a fourth travel limit mechanism 184 that can limit the amount of travel of fourth engagement member 180.

In one or more arrangements, a third engagement member biasing mechanism 175 is positioned and/or arranged to apply a biasing force to third engagement member 170 to bias and/or move third engagement member 170 beyond the periphery 127 of the right side 128 of the electronics tray 120 to engage, contact, and/or be secured to the electronics tray 120, for example to be contained within a holding chamber formed and/or configured in the electronics rack 100. In an embodiment, third engagement member biasing mechanism 175 includes a spring element 176, for example a compression and/or helical spring. Spring element 176 is positioned and/or arranged between the electronics tray 120 and the third engagement member 170, for example a portion of third engagement member 170, to apply a force to the third engagement member 170 to move and/or bias the third engagement member 170 to extend beyond the periphery 127 of the electronics tray 120 and into a position (e.g., within a holding chamber formed and/or configured in the electronics rack) to secure the electronics tray 120 in position within the electronics rack 100. Movement of third engagement member 170 in one or more approaches is limited by one or more of projections 172 contacting and/or engaging the ends of recesses 173.

In one or more arrangements, a fourth engagement member biasing mechanism 185 is positioned and/or arranged to apply a biasing force to fourth engagement member 180 to bias and/or move fourth engagement member 180 beyond the periphery 127 of the left side 129 of the electronics tray 120 to engage, contact, and/or be secured to the electronics tray 120, for example to be contained within a holding chamber formed and/or configured within electronics rack 100. In an embodiment, fourth engagement member biasing mechanism 185 includes a spring element 186, for example a compression and/or helical spring. Spring element 186 is positioned and/or arranged between the electronics tray 120 and the fourth engagement member 180, for example a portion of fourth engagement member 180, to apply a force to the fourth engagement member 180 to move and/or bias the fourth engagement member 180 to extend beyond the periphery 127 of the electronics tray 120 and into a position (e.g., within a holding chamber formed and/or configured in the electronics rack) to secure the electronics tray 120 in position within the electronics rack 100. Movement of fourth engagement member 180 in one or more approaches is limited by one or more of projections 182 contacting and/or engaging the ends of recesses 183.

Third engagement member 170 and fourth engagement member 180 in one or more configurations each include one or more user interface surfaces for a user to apply a force to move respective third engagement member 170 and fourth engagement member 180. The user interface surfaces facilitate a user applying force to the third and/or fourth engagement members 170, 180 to move respective third and/or fourth engagement members 170, 180 against the biasing force provided by the third engagement member biasing mechanism 175 and the fourth engagement member biasing mechanism 185.

Third engagement member 170 in an embodiment has a third projecting end 177 that in an arrangement has a third engagement surface 178 and a third interface group 179. That is, third projecting end 177, which has at least a portion that is configured and arranged to extend beyond the periphery 127 of the right side 128 of the electronics tray 120, in response to third engagement member 170 being in an extension position, has a third engagement surface 178 that is configured to engage and/or contact a corresponding third engaging surface 194 of the electronics tray 120 to inhibit, impede, and/or prevent movement and/or removal of electronics tray 120 within the electronics rack 100.

With third engagement member 170 in an extension position, removing electronics tray 120 from electronics rack 100 is inhibited, impeded and/or prevented as third engagement surface 178 contacts and engages a portion, e.g., corresponding third engaging surface 194, of electronics rack 100. In an embodiment, third engagement surface 178 is substantially perpendicular to the movement of electronics tray 120 during installation and/or removal from electronics rack 100. That is, third engagement surface 178 is configured to be perpendicular to, or substantially perpendicular to, the longitudinal axis 131 of electronics tray 120 and in an embodiment is aligned with longitudinal axis 171 of third engagement member 170. In one or more approaches, third engagement surface 178 is aligned in the direction of movement of third engagement member 170 relative to electronics tray 120. With third engagement member 170 in a retracted position, third engagement surface 178 of third engagement member 170 is moved to a position such that third engagement surface 178 does not and will not contact or engage a portion of electronics rack 100 facilitating and/or permitting movement and/or removal of electronics tray 120 from electronics rack 100.

Fourth engagement member 180 is similar to the configuration of third engagement member 170 and is positioned within electronics tray 120 and operates in a manner similar to third engagement member 170, but fourth engagement member 180 is positioned on the left side 129 of electronics tray 120. Fourth engagement member 180 in an embodiment has a fourth projecting end 187 that in an arrangement has a fourth engagement surface 188 and a fourth interface group 189. That is, fourth projecting end 187 that is configured and arranged to extend beyond the periphery 127 of the left side 129 of the electronics tray 120, in response to fourth engagement member 180 being in an extension position, has a fourth engagement surface 188 that is configured to engage and/or contact a corresponding fourth engaging surface 199 of the electronics tray 120 to inhibit, impede, and/or prevent movement and/or removal of electronics tray 120 within the electronics rack 100.

With fourth engagement member 180 in an extension position, removing electronics tray 120 from electronics rack 100 is inhibited, impeded and/or prevented as fourth engagement surface 188 contacts and engages a portion, e.g., corresponding fourth engaging surface 199, of electronics rack 100. In an embodiment, fourth engagement surface 188 is substantially perpendicular to the movement of electronics tray 120 during installation and/or removal from electronics rack 100. That is, fourth engagement surface 188 is configured to be perpendicular to, or substantially perpendicular to, the longitudinal axis 131 of electronics tray 120 and in an embodiment is aligned with the longitudinal axis 181 of the fourth engagement member 180. In one or more approaches, fourth engagement surface 188 is aligned in the direction of movement of fourth engagement member 180 relative to electronics tray 120. With fourth engagement member 180 in a retracted position, fourth engagement surface 188 of electronics tray 120 is moved to a position such that fourth engagement surface 188 does not and will not contact or engage a portion of electronics rack 100 facilitating and/or permitting movement and/or removal of electronics tray 120 from electronics rack 100.

While third and fourth engagement surfaces 178, 188 have been described and illustrated as being perpendicular to longitudinal axis 171, 181 of third and fourth engagement members 170, 180 it can be appreciated that third and fourth engagement surfaces 178, 188 can be inclined or sloped (e.g., not perpendicular with respect to longitudinal axis 171, 181) but preferably are shaped and configured to engage and/or contact structure in electronics rack 100 to inhibit, impede, and/or prevent movement of electronics tray 120 until a user applied force moves the third and fourth engagement members 170, 180 in a retraction direction so that third and fourth engagement surfaces 178, 188 no longer contact and/or engage blocking structures in electronics rack 100.

Third engagement member 170 in one or more embodiments has third interface group 179, e.g., third inclined surface 179, which is configured to engage a corresponding structure on the electronics rack 100 to move and/or retract third engagement member 170 in response to frontward movement of electronics tray 120 relative to electronics rack 100. That is, in one or more arrangements, as electronics tray 120 is moved frontward toward the front 102 of electronics rack 100, third interface group 179 contacts structure in the electronics rack 100 such that in response to further frontward movement of electronics tray 120 in electronics rack 100, third engagement member 170 retracts, e.g., moves in channel 166 perpendicular (or substantially perpendicular) to the longitudinal axis 131 of electronics tray 120, such that third engagement member 170 can move past (e.g., frontward of) the electronics rack structure. By applying a force (e.g., a user applied force) to electronics tray 120 in a frontward direction (e.g., toward the front 102 of electronics rack 100) and/or by moving electronics tray 120 in a frontward direction, third interface group 179, e.g., third inclined surface 179, contacts structure in electronics rack 100, which moves third engagement member 170 against the force/resistance applied by third engagement member biasing mechanism 175, e.g., against the force/resistance from spring element 176. Third interface group 179 is illustrated as an inclined surface 179, but it can be appreciated that third interface group 179 can include one or more of inclined surfaces, rounded surfaces, and/or rollers.

Fourth engagement member 180 in one or more embodiments also has a fourth interface group 189 which is configured to engage a corresponding structure on the electronics rack 100 to move and/or retract fourth engagement member 180 in response to frontward movement of electronics tray 120 relative to electronics rack 100. That is, as electronics tray 120 is moved frontward toward the front 102 of electronics rack 100, fourth interface group 189 contacts structure in the electronics rack 100 such that in response to further frontward movement of electronics tray 120 in electronics rack 100, fourth engagement member 180 retracts, e.g., moves in channel 166 perpendicular to the longitudinal axis 131 of electronics tray 120, such that fourth engagement member 180 can move past the electronics rack structure. By applying a force (e.g., a user applied force) to electronics tray 120 in a frontward direction (toward the front 102 of the electronics rack 100) and/or by moving electronics tray 120 in a frontward direction, fourth interface group 189, e.g., fourth inclined surface 189 contacts structure in electronics rack 100, which moves fourth engagement member 180 against the force applied by fourth engagement member biasing mechanism 185, e.g., against the force from spring element 186. Fourth interface group 189 is illustrated as an inclined surface 189, but it can be appreciated that fourth interface group 189 can include one or more of inclined surfaces, rounded surfaces, and/or rollers.

It can be appreciated that the third and fourth interface groups 179, 189 can be varied, e.g., the slope of inclined surfaces 179, 189 can be varied, as can the structure of the electronics rack 100 that contacts, engages, and/or moves third and fourth engagement members 170, 180 (e.g., third and fourth projecting ends 177, 188), and the biasing forces (e.g., the spring constants of spring elements 176, 186) and configurations of the third and fourth engagement member biasing mechanisms 175, 185 can also be varied to adjust and configure the force necessary to move and/or slide third and fourth engagement members 170, 180, and accordingly move electronics tray 120 toward the front 102 of the electronics rack 100. The inclined surfaces 179, 189 preferably have an incline angle between about 30-60 degrees with respect to the side (e.g., the right side 128 or the left side 129) of the electronics tray 120, more preferable between about 40-50 degrees, for example about 45 degrees, although other incline angles for inclined surfaces 179, 189 that are less than 30 degrees and more than 60 degrees are contemplated. It can be appreciated that rollers, curved surfaces, and/or other structures can be implemented to contact and engage structure in the electronics rack 100, other than inclined surfaces 179, 189, to move and/or retract third and fourth engagement members 170, 180.

Each of first, second, third, and fourth engagement members 140, 150, 170, 180 are associated with a holding mechanism to temporarily hold and/or retain the respective engagement members 140, 150, 170, 180 in a retracted position so that projecting ends 147, 157, 177, 187 of respective engagement members 140, 150, 170, 180 do not extend beyond the periphery 127 of the electronics tray 120 and/or are held in a position that permits the engagement members 140, 150, 170, 180 to clear any structure of the electronics rack 100 that may block, inhibit, impede and/or prevent movement, e.g., horizontal movement, of electronics tray 120 in electronics rack 100. In an embodiment, respective temporary holding mechanisms 110, 111, 112, 113 may comprise a small recess or detent on each respective engagement member 140, 150, 170, 180 that interacts with structure on the electronics tray 120, e.g., a pin projection, to temporarily hold the respective engagement member 140, 150, 170, 180 in a retracted position against the bias force of the engagement member biasing mechanisms 145, 155, 175, 185. Other mechanisms are contemplated to temporarily hold engagement members 140, 150, 170, 180 in a retracted position.

### EXAMPLES

Example 1: An electronics tray configured to contain multiple electronic components, the electronics tray comprising an attachment mechanism at each end of the electronics tray configured to contain the electronics tray in an electronics rack or a subassembly of the electronics rack and permit multi-directional installation and/or removal of the electronics tray from the electronics rack or the subassembly of the electronics rack.

Example 2: The electronics tray according to example 1, wherein at least one of the attachment mechanisms, and preferably the attachment mechanism at each end of the electronics rack, comprises a biasing mechanism wherein the biasing mechanism biases the attachment mechanism to a first extended position where the attachment mechanism is contained within a securing portion of the electronics rack or the subassembly of the electronics rack to secure the electronics tray in the electronics rack or the subassembly of the electronics rack.

Example 3: The electronics tray according to examples 1 or 2, wherein the at least one of the attachment mechanisms, preferably the attachment mechanism at each end of the electronics tray, comprises at least two engagement members on opposite sides of the electronics tray to each be contained within a different securing portion of the electronics rack or the subassembly of the electronics rack to secure the electronics tray within the electronics rack or the subassembly of the electronics rack.

Example 4: The electronics tray according to example 3, wherein at least one, preferably each, engagement member comprises an engagement member biasing mechanism to bias the respective engagement member to a first extended position such that each respective engagement member is containable within a respective different securing portion of the electronics rack or the subassembly of the electronics rack to secure the electronics tray to the electronics rack or the subassembly of the electronics rack.

Example 5: The electronics tray according to example 4, wherein each engagement member biasing mechanism comprises a spring element.

Example 6: The electronics mechanism according to example 5, wherein each respective spring element engages a different portion of the electronics tray and a different portion of each respective engagement member to bias the respective engagement member to the first extended position.

Example 7: The electronics tray according to example 5, wherein the spring element is a compression spring.

Example 8: The electronics tray according to example 3, wherein each respective engagement member is moveable to a second retracted position where each respective engagement member does not engage the respective different securing portions within the electronics rack or the subassembly of the electronics rack.

Example 9: The electronics tray according to example 3, wherein each respective engagement mechanism is movable in a direction perpendicular to a direction of moving the electronics tray within the electronics rack or the subassembly of the electronics rack during installation or removal of the electronics tray from the electronics rack or the subassembly of the electronics rack.

Example 10: The electronics tray according to example 3, wherein each engagement member comprises at least one recess to engage at least one projection associated with the electronics tray to guide movement of each respective engagement member relative to the electronics tray.

Example 11: The electronics tray according to example 10, wherein each engagement member comprises at least two recesses wherein each recess engages at least one respective projection associated with the electronics tray wherein each respective projection guides movement of each respective engagement member relative to the electronics tray.

Example 12: The electronics tray according to example 3, wherein each engagement member comprises a travel limit mechanism to limit the amount of distance each respective engagement member travels relative to the electronics tray.

Example 13: The electronics tray according to example 3, wherein at least one engagement member comprises an interface group configured to contact corresponding structure in the electronics rack or the subassembly of the electronics rack in response to moving the electronics tray to move the at least one engagement member so that the at least one engagement member is not contained in a securing portion in the electronics rack or the subassembly of the electronics rack, wherein the interface group includes at least one of: an inclined surface, a rounded surface, a roller, and combinations thereof.

Example 14: The electronics tray according to example 13, wherein the at least one engagement member comprises an engagement surface that inhibits movement of the electronics tray by contacting an engaging surface in the electronics rack or the subassembly of the electronics rack.

Example 15: The electronics tray according to example 14, wherein the securing portion comprises a holding chamber formed by: an engaging surface that interacts with the engagement surface of the at least one engagement member to inhibit movement of the electronics tray, and at least one of an interface group configured to move the at least one engagement member to permit movement of the electronics tray, the interface group consisting of at least one of: an inclined surface, a rounded surface, a roller, and combinations thereof.

Example 16: The electronics tray according to example 13, wherein the at least one engagement member moves against a biasing force of an engagement member biasing mechanism in response to moving the electronics tray within the electronics rack or the subassembly of the electronics rack.

Example 17: The electronics tray according to example 16, wherein the at least one engagement member is user moveable to a second retracted position where the engagement member is not contained in the securing portion of the electronics rack or the subassembly of the electronics rack.

Example 18: The electronics tray according to example 17, wherein the electronics tray comprises a holding mechanism to hold the at least one engagement member in the second retracted position where the at least one engagement member is not contained within the securing portion of the electronics rack or the subassembly of the electronics rack.

Example 19: The electronics tray according to example 18, wherein the holding mechanism comprises a detent to interact with structure on the electronics tray to temporarily hold the at least one engagement member in the second retracted position.

### Example Uses: Installation

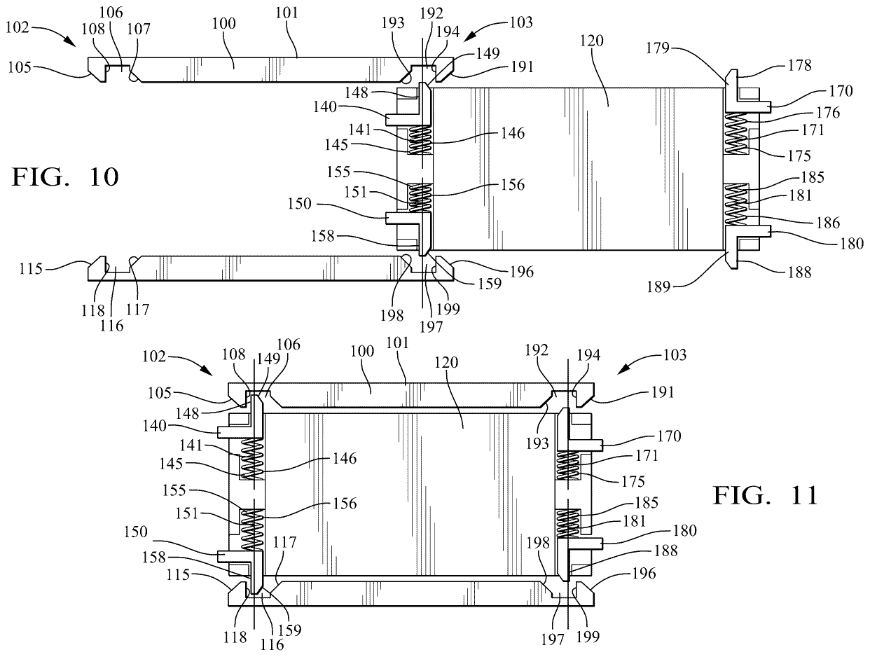

FIGS. 8-10 illustrates example multi-directional (e.g., bidirectional) installations of electronics tray 120 in electronics rack 100, where FIGS. 8-9 illustrates installation of electronics tray 120 from front 102 of electronics rack 100 and FIGS. 10 and 9 illustrate installation of electronics tray from the rear 103 of electronics rack 100. As shown in FIG. 8, to install electronics tray 120 into and/or from the front 102 of the electronics rack 100, in an approach, the second attachment mechanism 160 is moved to a retracted position, and in one or more arrangements, third engagement member 170 and fourth engagement member 180 are moved to a retracted position, so that electronics tray can be moved in a rearward direction. Continued movement of electronics tray 120 in a rearward direction moves the electronics tray 120 into an installation position as shown in FIG. 9 where engagement members 140, 150, 170, 180 extend beyond the periphery 127 of the electronics tray and the projecting ends 147, 157, 177, 187 are each positioned in a respective holding chamber 106, 116, 192, 197 formed and/or configured in the electronics rack 100.

In one or more embodiments, the second attachment mechanism 160, and/or the third and fourth engagement members 170, 180, are retained in a retracted position against the force of the third and fourth engagement member biasing mechanism 175, 185 by temporary third and fourth holding mechanism 112, 113. For example, in an embodiment, a user can move the second attachment mechanism 160, and in an arrangement move each of third and fourth engagement members 170, 180 to the retracted position and engage the temporary third and fourth holding mechanisms 112, 113 to hold the respective third and fourth engagement members 170, 180 temporarily in position. With the third and fourth engagement members 170, 180 temporarily held in the retracted position the electronics tray 120 can be moved rearward toward the installation position. The respective temporary third and fourth holding mechanism 112, 113 releases the third and fourth engagement members 170, 180 so that the third and fourth engagement members extend into respective holding chambers 192, 197.

Alternatively, and/or additionally, installation of electronics tray 120 from the front 102 of the electronics rack can proceed by moving electronics tray 120 rearward into position such that projecting ends 177, 187 of the third and fourth engagement members 170, 180 contact and engage a structure, e.g., one or more inclined surfaces, on the electronics rack 100 which moves the respective third and fourth engagement members 170, 180 inward to a retracted position such that electronics tray 120 is permitted to move in a rearward direction from the front 102 of the electronics rack 100 toward the rear 103 of the electronics rack 100.

For example, as electronics tray 120 is moved horizontally into the front 102 of the electronics rack, third projecting end 177 of third engagement member 170 contacts and engages first structure group 105, e.g., first inclined surface 105, on electronics rack 100 which moves projecting end 177 inward, whereupon further rearward movement of electronics tray 120 has projecting end 177 move into an extended position in first holding chamber 106 of electronics rack 100, whereupon further rearward movement of electronics tray 120 has projecting end 177 contact and engage second structure group 107, e.g., second inclined surface 107, on electronics rack 100 which moves projecting end 177 inward out of and past first holding chamber 106. Similarly, for example, as electronics tray 120 is moved horizontally into the front 102 of the electronics rack 100 and projecting end 177 undergoes the movement described above, fourth projecting end 187 of fourth engagement member 180 contacts and engages third structure group 115, e.g. third inclined surface 115, on electronics rack 100 which moves fourth projecting end 187 inward, whereupon further rearward movement of electronics tray 120 has fourth projecting end 187 move into an extended position in second holding chamber 116 of electronics rack 100, whereupon further rearward movement has fourth projecting end 187 contact and engage fourth structure group 117, e.g., fourth inclined surface 117, on electronics rack 100 which moves fourth projecting end 187 inward out of and past second holding chamber 116. First, second, third and fourth structure group 105, 107, 115, 117 are illustrated as inclined surfaces 105, 107, 115, 117, but it can be appreciated that structure groups 105, 107, 115, 117 can include one or more of inclined surfaces, rounded surfaces, and/or rollers. The inclined surfaces of first, second, third, and fourth structure groups 105, 107, 115, 117 preferably have an incline angle between about 30-60 degrees with respect to the side (e.g., the right side 128 or the left side 129) of the electronics tray 120, more preferable between about 40-50 degrees, for example about 45 degrees, although other incline angles for the surfaces of structure groups 105, 107, 115, 117 that are less than 30 degrees and more than 60 degrees are contemplated.

Further movement of electronics tray 120 rearward in electronics rack 100 toward the rear 103 of the electronics rack 100 has first attachment mechanism 130, and in an embodiment first and second engagement members, which are in the extended position, contact electronics rack structure which will move first attachment mechanism 130, including in an arrangement first and second engagement members 140, 150, inward toward or into the retracted position. More specifically, as electronics tray 120 is moved further rearward, first and second projecting ends 147, 157 of first and second engagement members 140, 150 will engage first and third structure groups 105, 115 which will move projecting ends 147, 157 inward to a retracted position permitting further rearward movement of electronics tray 120. As electronics moves further rearward, projecting ends 147, 157 move to extended positions into first and second holding chambers 106, 116 and third and fourth projecting ends 177, 187 move to extending positions into third and fourth holding chambers 192, 197 as shown in FIG. 9.

More specifically, in one or more approaches, as projecting ends 147, 157 move rearward past first and third structure groups 105, 115, the projecting ends 147, 157 move outward by the force applied by respective first and second engagement member biasing mechanisms 145, 155 (e.g., spring elements 146, 156) beyond the periphery 127 of the electronics tray into extended positions and into respective first and second holding chambers 106, 116. In addition, as electronics tray 120 moves rearward, third projecting end 177 contacts fifth structure group 191, e.g., fifth inclined surface 191, where under the force applied by third engagement member biasing mechanism 175 (e.g., spring element 176) third engagement member 170 moves outward and projecting end 177 moves into third holding chamber 192. Similarly, as electronics tray 120 moves rearward, fourth projecting end 187 contacts seventh structure group 196, e.g., seventh inclined surface 196, where under the force applied by fourth engagement member biasing mechanism 185 (e.g., spring element 186) fourth engagement member 180 moves outward and fourth projecting end 187 moves into fourth holding chamber 197.

With the projecting ends 147, 157, 177, 187 in respective holding chambers 106, 116, 192, 197 as shown in FIG. 9, the electronics tray 120 has been installed into the installation position in the electronics rack 100 from the front 102 of the electronics rack 100. Further rearward movement of electronics tray 120 will cause third engagement surface 178 and fourth engagement surface 188 to contact and/or engage structure (e.g., respective third and fourth engaging surfaces 194, 199) on electronics rack 100 to inhibit, impede, block, and/or otherwise prevent further rearward movement of electronics tray 120 within electronics rack 100. In addition, frontward movement of electronics tray 120 will cause first engagement surface 148 and second engagement surface 158 to contact and/or engage structure (e.g., respective first and second engaging surfaces 108, 118) on electronics rack 100 to inhibit, impede, block, and/or otherwise prevent frontward movement of electronics tray 120 within electronics rack 100. While in the installation position, e.g., where respective projecting ends 147, 157, 177, 187 are contained within respective holding chambers 106, 116, 192, 197, the electronics tray preferably cannot be removed, e.g., moved, without a user applied force applied to first attachment mechanism 130, for example first and second engagement members 140, 150, and/or to second attachment mechanism 160, for example third and fourth engagement members 170, 180.

As shown in FIG. 10, to install electronics tray 120 into and/or from the rear 103 of the electronics rack 100, in an approach, the first attachment mechanism 130 is moved to a retracted position, and in one or more arrangements, first engagement member 140 and second engagement member 150 are moved to a retracted position, so that electronics tray 120 can be moved in a frontward direction (e.g., toward the front 102 of the electronics rack 100). Continued movement of electronics tray 120 in a frontward direction moves the electronics tray 120 into an installation position as shown in FIG. 9 where engagement members 140, 150, 170, 180 extend beyond the periphery 127 of the electronics tray and the projecting ends 147, 157, 177, 187 are each positioned in a respective holding chamber 106, 116, 192, 197 formed and/or configured in the electronics rack 100.

In one or more embodiments, the first attachment mechanism 130, and/or the first and second engagement members 140, 150, are retained in a retracted position against the force of the first and second engagement member biasing mechanism 145, 155 by temporary first and second holding mechanisms 110, 111. For example, in an embodiment, a user can move the first attachment mechanism 130, and in an arrangement move each of first and second engagement members 140, 150 to the retracted position and engage the temporary first and second holding mechanisms 110, 111 to hold respective first and second engagement members 140, 150 temporarily in position. With the first and second engagement members 140, 150 temporarily held in the retracted position the electronics tray 120 can be moved frontward to the installation position. The respective temporary first and second holding mechanisms 110, 111 release the first and second engagement members 140, 150 so that the first and second engagement members 140, 150 extend into respective first and second holding chambers 106, 116.

Alternatively, and/or additionally, installation of electronics tray 120 from the rear 103 of the electronics rack 100 can proceed by moving electronics tray 120 frontward (e.g., toward the front 102 of electronics rack 100) into position such that projecting ends 147, 157 of the first and second engagement members 140, 150 contact and engage a structure, e.g., one or more inclined surfaces, on the electronics rack 100 which moves the respective first and second engagement members 140, 150 inward to a retracted position such that electronics tray 120 is permitted to move in a frontward direction from the rear 103 of the electronics rack 100 toward the front 102 of the electronics rack 100.

For example, as electronics tray 120 is moved horizontally into the rear 103 of the electronics rack 100, first projecting end 147 of first engagement member 140 contacts and engages fifth structure group 191, e.g., fifth inclined surface 191, on electronics rack 100 which moves projecting end 147 inward, whereupon further frontward movement of electronics tray 120 has projecting end 147 move into an extended position in third holding chamber 192 of electronics rack 100, whereupon further frontward movement of electronics tray 120 has projecting end 147 contact and engage sixth structure group 193, e.g., inclined surface 193, on electronics rack 100 which moves projecting end 147 inward, out of, and past third holding chamber 192. Similarly, for example, as electronics tray 120 is moved horizontally into the rear 103 of the electronics rack 100 and projecting end 147 undergoes the movement described above, second projecting end 157 of second engagement member 150 contacts and engages seventh structure group 196, e.g., seventh inclined surface 196, on electronics rack 100 which moves second projecting end 157 inward, whereupon further frontward movement of electronics tray 120 has second projecting end 157 move into an extended position in fourth holding chamber 197 of electronics rack 100, whereupon further rearward movement has second projecting end 157 contact and engage eighth structure group 198, e.g., eighth inclined surface 198, on electronics rack 100 which moves projecting end 157 inward, out of, and past fourth holding chamber 197. Fifth, sixth, seventh, and eighth structure group 191, 193, 196, 198 are illustrated as inclined surfaces 191, 193, 196, 198, but it can be appreciated that structure groups 191, 193, 196, 198 can include one or more of inclined surfaces, rounded surfaces, and/or rollers. The inclined surfaces of fifth, sixth, seventh, and eighth structure groups 191, 193, 196, 198 preferably have an incline angle between about 30-60 degrees with respect to the side (e.g., the right side 128 or the left side 129) of the electronics tray 120, more preferable between about 40-50 degrees, for example about 45 degrees, although other incline angles for the surfaces of structure groups 191, 193, 196, 198 that are less than 30 degrees and more than 60 degrees are contemplated.

Further movement of electronics tray 120 frontward in electronics rack 100 toward the front 102 of the electronics rack 100 has second attachment mechanism 160, and in an embodiment third and fourth engagement members 170, 180, which are in the extended position, contact electronics rack structure which will move second attachment mechanism 160, including in an arrangement third and fourth engagement members 170, 180, inward toward or into the retracted position. More specifically, as electronics tray 120 is moved further frontward, third and fourth projecting ends 177, 187 of third and fourth engagement members 170, 180 will engage fifth and seventh structure groups 191, 196, e.g., inclined surfaces 191, 196, which will move third and fourth projecting ends 177, 187 inward to a retracted position permitting further frontward movement of electronics tray 120. As electronics tray 120 moves further frontward, third and fourth projecting ends 177, 187 move to extended positions into third and fourth holding chambers 192, 197 and projecting ends 147, 157 move to extending positions into first and second holding chambers 106, 116 as shown in FIG. 9.

More specifically, in one or more approaches, as third and fourth projecting ends 177, 187 move frontward past fifth and seventh structure groups, e.g., inclined surfaces 191, 196, the third and fourth projecting ends 177, 187 move outward by the force applied by respective third and fourth engagement member biasing mechanisms 175, 185 (e.g., spring elements 176, 186) beyond the periphery 127 of the electronics tray 120 into extended positions and into respective third and fourth holding chambers 192, 197. In addition, as electronics tray 120 moves frontward, first projecting end 147 of first engagement member 140 contacts second structure group 107, e.g., second inclined surface 107, where under the force applied by first engagement member biasing mechanism 145 (e.g., spring element 146) first engagement member 140 moves outward and projecting end 147 moves into first holding chamber 106. Similarly, as electronics tray 120 moves frontward, second projecting end 157 contacts fourth structure group 117, e.g., inclined surface 117, where under the force applied by second engagement member biasing mechanism 155 (e.g., spring element 156) second engagement member 150 moves outward and second projecting end 157 moves into second holding chamber 116.

With the projecting ends 147, 157, 177, 187 in respective holding chambers 106, 116, 192, 197 as shown in FIG. 9, the electronics tray 120 has been installed in the installation position in the electronics rack 100 from the rear 103 of the electronics rack 100. Further frontward movement of electronics tray 120 will cause first engagement surface 148 and second engagement surface 158 to contact and/or engage structure (e.g., respective first and second engaging surfaces 108, 118) on electronics rack 100 to inhibit, impede, block, and/or otherwise prevent further rearward movement of electronics tray 120 within electronics rack 100. In addition, rearward movement of electronics tray 120 will cause third engagement surface 178 and fourth engagement surface 188 to contact and/or engage structure (e.g., respective third and fourth engaging surfaces 194, 199) on electronics rack 100 to inhibit, impede, block, and/or otherwise prevent rearward movement of electronics tray 120 within electronics rack 100. While in the installation position, e.g., where respective projecting ends 147, 157, 177, 187 are contained within respective holding chambers 106, 116, 192, 197, the electronics tray preferably cannot be removed, e.g., moved, without a user applied force applied to first attachment mechanism 130, for example first and second engagement members 140, 150, and/or to second attachment mechanism 160, for example third and fourth engagement members 170, 180.

### Example Uses: Removal

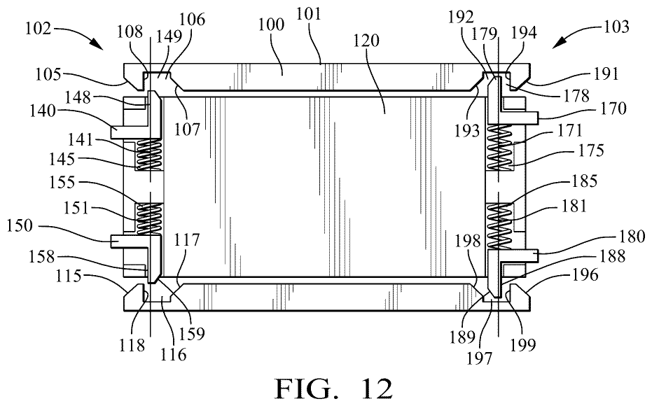

FIGS. 11-12 illustrates example bi-directional removal operations of electronics tray 120 from electronics rack 100, where FIG. 11 illustrates removal of electronics tray 120 from an installation position as shown in FIG. 9 from the rear 103 of electronics rack 100 and FIG. 12 illustrates removal of electronics tray 120 from the installation position shown in FIG. 9 from the front 102 of electronics rack 100.

As shown in FIG. 11, in an approach, to remove the electronics tray 120 from the rear 103 of the electronics rack 100, the second attachment mechanism 160 is moved to a retracted position, and in one or more arrangements, third engagement member 170 and fourth engagement member 180 are moved to a retracted position, so that electronics tray 120 can be moved (e.g., pulled horizontally) in a rearward direction (e.g., toward the rear 103 of the electronics rack 100). That is, the second attachment mechanism 160 is moved to a retracted position where in an embodiment the third engagement member 170 is retracted so that third projecting end 177 is no longer positioned within third holding chamber 192 permitting rearward movement of electronics tray 120 in electronics rack 100. Similarly, the second attachment mechanism 160 is moved to a retracted position where in an embodiment the fourth engagement member 180 is also retracted so that fourth projecting end 187 is no longer positioned within fourth holding chamber 197 permitting rearward movement of electronics tray 120 in electronics rack 100. Continued movement of electronics tray 120 in a rearward direction permits removal of electronics tray 120 from the electronics rack as shown in FIG. 10.

In one or more embodiments, to remove the electronics tray from the rear 103 of the electronics rack, the second attachment mechanism 160, and in an arrangement the third and fourth engagement members 170, 180, are retained in a retracted position against the force of the third and fourth engagement member biasing mechanism 175, 185 by temporary third and fourth holding mechanisms 112, 113. For example, in an embodiment, a user can move the second attachment mechanism 160, and in an arrangement move each of third and fourth engagement members 170, 180 to the retracted position and engage the temporary third and fourth holding mechanisms 112, 113 to hold each of respective third and fourth engagement members 170, 180 temporarily in position. With the third and fourth engagement members 170, 180 temporarily held in the retracted position the electronics tray 120 can be moved rearward to permit removal of electronics tray 120. That is, with the third and fourth engagement members 170, 180 retracted from the third and fourth holding chambers 192, 197, a user can move the electronics tray 120 rearward (e.g., toward the rear 103 of the electronics rack 100).

Alternatively, and/or additionally, removal of electronics tray 120 from the rear 103 of the electronics rack 100 can proceed by moving second attachment mechanism 160, and in an embodiment third and fourth engagement members 170, 180 inward to the retracted position, and pulling rearward on the electronics tray 120. As electronics tray 120 is moved rearward, projecting ends 147, 157 of the first and second engagement members 140, 150 contact and engage a structure, e.g., one or more inclined surfaces, on the electronics rack 100 which moves the respective first and second engagement members 140, 150 inward to a retracted position such that electronics tray 120 is permitted to move in a rearward direction from the front 102 of the electronics rack 100 toward the rear 103 of the electronics rack 100.

For example, in one or more approaches, as electronics tray 120 is moved (e.g., pulled) rearward, preferably horizontally, out of the rear 103 of the electronics rack 100, first projecting end 147, for example first interface group 149 of first engagement member 140, contacts and engages second structure group 107 on electronics rack 100 which moves projecting end 147, more specifically first interface group 149, inward to a retracted position, and out of and/or past first holding chamber 106 of electronics rack 100, whereupon in a configuration in response to further rearward movement of electronics tray 120, projecting end 147 contacts and engages sixth structure group 193 on electronics rack 100 which permits and/or causes projecting end 147 to move outward to an extended position and into third holding chamber 192 formed and/or configured in electronics rack 100. In response to further rearward movement of electronics tray 120, in a configuration, projecting end 147, more specifically first interface group 149 of projecting end 147, contacts and/or engages third engaging surface 194 whereupon first engagement member 140 retracts so that projecting end 147 is no longer located within third holding chamber 192 and moves out of third holding chamber 192 so that electronics tray 120 is permitted to be removed from the rear 103 of the electronics rack 100.

Similarly, for example, in one or more approaches as electronics tray 120 is moved (e.g., pulled) rearward, preferably horizontally, out of the rear 103 of the electronics rack 100 and projecting end 147 undergoes the movement discussed above upon rearward movement of electronics tray 120, second projecting end 157, for example second interface group 159 of second engagement member 150, contacts and engages fourth structure group 117 on electronics rack 100 which moves second projecting end 157, more specifically second interface group 159, inward to a retracted position, and out of and/or past second holding chamber 116 of the electronics rack 100, whereupon in a configuration in response to further rearward movement of electronics tray 120, projecting end 157 contacts and engages eighth structure group 198 on electronics rack 100 which permits and/or causes projecting end 157 to move outward to an extended position and into fourth holding chamber 197 formed and/or configured in electronics rack 100. In response to further rearward movement of electronics tray 120, in a configuration projecting end 157, more specifically second interface group 159 of projecting end 157, contacts and/or engages fourth engaging surface 199 on electronics rack 100 whereupon second engagement member 150 retracts so that projecting end 157 moves inward and is no longer within fourth holding chamber 197 and moves out of fourth holding chamber 197 so that electronics tray 120 is permitted to be removed from the rear 103 of the electronics rack 100.

It can be appreciated, that upon moving second attachment mechanism 160, in one or more example arrangements upon moving engagement members 170, 180, inward in a retraction direction to remove engagement members 170, 180 out of third and fourth holding chambers 192, 198, and having first and second interface groups 149, 159 of first and second engagement members 140, 150 engage and contact second and fourth structure groups surfaces 107, 117 to retract projecting ends 147, 157 to remove projecting ends 147, 157 from first and second holding chambers 106, 116 the electronics tray can be moved rearwardly to permit removal of electronics tray 120 from electronics rack 100.

As shown in FIG. 12, in an approach, to remove the electronics tray 120 from the front 102 of the electronics rack 100, the first attachment mechanism 130 is moved preferably by a user to a retracted position, and in one or more arrangements, first engagement member 140 and second engagement member 150 are moved to a retracted position, so that electronics tray 120 can be moved (e.g., pulled horizontally) in a frontward direction (e.g., toward the front 102 of the electronics rack 100). That is, the first attachment mechanism 130 is moved to a retracted position where in an embodiment the first engagement member 140 is retracted so that projecting end 147 is no longer positioned within first holding chamber 106 permitting frontward movement of electronics tray 120 in electronics rack 100. Similarly, the first attachment mechanism 130 is moved to a retracted position where in an embodiment the second engagement member 150 is also retracted so that second projecting end 157 is no longer positioned within second holding chamber 116 permitting frontward movement of electronics tray 120 in electronics rack 100. Continued movement of electronics tray 120 in a frontward direction permits removal of electronics tray 120 from the electronics rack as shown in FIG. 8.

In one or more embodiments, to remove the electronics tray from the front 102 of the electronics rack, the first attachment mechanism 130, and in an arrangement the first and second engagement members 140, 150, are retained in a retracted position against the force of the first and second engagement member biasing mechanism 145, 155 by temporary first and second holding mechanisms 110, 111. For example, in an embodiment, a user can move the first attachment mechanism 130, and in an arrangement move each of first and second engagement members 140, 150 to the retracted position and engage the temporary first and second holding mechanisms 110, 111 to hold each of respective first and second engagement members 140, 150 temporarily in position. With the first and second engagement members 140, 150 temporarily held in the retracted position the electronics tray 120 can be moved frontward (e.g., pulled forward) to permit removal of electronics tray 120. That is, with the first and second engagement members 140, 150 retracted from the first and second holding chambers 106, 116, a user can move the electronics tray 120 frontward (e.g., toward the front 102 of the electronics rack 100).

Alternatively, and/or additionally, removal of electronics tray 120 from the front 102 of the electronics rack 100 can proceed by moving first attachment mechanism 130, and in an embodiment first and second engagement members 140, 150, inward to the retracted position and pulling frontward on the electronics tray 120. As electronics tray 120 is moved frontward, third and fourth projecting ends 177, 187 of the third and fourth engagement members 170, 180 contact and engage a structure, e.g., one or more inclined surfaces, on the electronics rack 100 which moves the respective third and fourth engagement members 170, 180 inward to a retracted position such that electronics tray 120 is permitted to move in a frontward direction from the rear 103 of the electronics rack 100 toward the front 102 of the electronics rack 100.

For example, in one or more approaches, as electronics tray 120 is moved (e.g., pulled) frontward, preferably horizontally, out of the front 102 of the electronics rack 100, third projecting end 177, for example third interface group 179 of third engagement member 170 contacts and engages sixth structure group 193 on electronics rack 100 which moves third projecting end 177, more specifically third interface group 179, inward to a retracted position, and out of and/or past third holding chamber 192 of electronics rack 100, whereupon in a configuration in response to further frontward movement of electronics tray 120, third projecting end 177 contacts and engages second structure group 107 on electronics rack 100 which permits and/or causes projecting end 177 to move outward to an extended position and into first holding chamber 106 formed and/or configured in electronics rack 100. In response to further frontward movement of electronics tray 120, in a configuration third projecting end 177, more specifically third interface group 179 of third projecting end 177, contacts and/or engages first engaging surface 108 whereupon third engagement member 170 retracts so that third projecting end 177 is no longer located within first holding chamber 106 and moves out of first holding chamber 106 so that electronics tray 120 is permitted to be removed from the front 102 of the electronics rack 100.

Similarly, for example, in one or more approaches, as electronics tray 120 is moved (e.g., pulled) frontward, preferably horizontally, out of the front 102 of the electronics rack 100 and third projecting end 177 undergoes the movement discussed above upon frontward movement of electronics tray 120, fourth projecting end 187, for example, fourth interface group 189 of fourth engagement member 180, contacts and engages eighth structure group 198 on electronics rack 100 which moves fourth projecting end 187, more specifically fourth interface group 189, inward to a retracted position, and out of and/or past fourth holding chamber 197 of electronics rack 100, whereupon in a configuration in response to further frontward movement of electronics tray 120, fourth projecting end 187 contacts and engages fourth structure group 117 on electronics rack 100 which permits and/or causes fourth projecting end 187 to move outward to an extended position and into second holding chamber 116 formed and/or configured in electronics rack 100. In response to further frontward movement of electronics tray 120, in a configuration fourth projecting end 187, more specifically fourth interface group 189, contacts and engages second engaging surface 118 on electronics rack 100 whereupon fourth engagement member 180 retracts so that fourth projecting end 187 moves inward and is no longer located within second holding chamber 116 and moves out of second holding chamber 116 so that electronics tray 120 is permitted to be removed from the front 102 of the electronics rack.

It can be appreciated, that upon moving first attachment mechanism 130, and in one or more arrangements upon moving first and second engagement members 140, 150 inward in a retraction direction to remove engagement members 140, 150 out of first and second holding chambers 106, 116, and having third and fourth interface groups 179, 189, e.g., third and fourth inclined surfaces 179, 189, of third and fourth engagement members 170, 180 engage and contact sixth and eighth structure groups, e.g., sixth and eighth inclined surfaces 193, 198, to retract third and fourth projecting ends 177, 187 and remove third and fourth projecting ends 177, 187 from third and fourth holding chambers 192, 197, the electronics tray 120 can be moved frontwardly to permit removal of electronics tray 120 from electronics rack 100.

### Further Uses

Use Example 1: A method of installing an electronics tray configured to contain a plurality of electronics components in an electronics rack that includes: moving a first attachment mechanism at a first end of the electronics tray to a retracted position wherein the first attachment mechanism is not securable within the electronics rack or a subassembly of the electronics rack; moving the electronics tray into an installation position in the electronics rack or the subassembly of the electronics rack; moving the first attachment mechanism, in response to the electronics tray being located in the installation position in the electronics rack or the subassembly of the electronics rack, to an extended position where the first attachment mechanism is contained within a first securing portion of the electronics rack or the subassembly of the electronics rack; and moving a second attachment mechanism at a second end of the electronics tray, in response to the electronics tray being located in the installation position in the electronics rack or the subassembly of the electronics rack, to an extended position where the second attachment mechanism is contained within a second different securing portion of the electronics rack or the subassembly of the electronics rack.

Use Example 2: The method according to use example 1, further including: moving the first attachment mechanism of the electronics tray to the retracted position against a first biasing force of a first biasing mechanism configured to move the first attachment mechanism to the extended position; and moving the second attachment mechanism of the electronics tray to the retracted position against a second biasing force of a second biasing mechanism configured to move the second attachment mechanism to the extended position.

Use Example 3: The method according to use example 2, wherein moving the second attachment mechanism of the electronics tray to the retracted position includes moving an interface group of the second attachment mechanism into contact with and relative to a corresponding structure in the electronics rack or the subassembly of the electronics rack to move the second attachment mechanism to the retracted position against the biasing force of the second biasing mechanism, wherein the interface group consists of at least one of: an inclined surface, a rounded surface, a roller, and combinations thereof.

Use Example 4: The method according to use example 3, further including upon moving the interface group of the second attachment mechanism beyond the corresponding structure of the electronics rack or the subassembly of the electronics rack so the interface group no longer contacts the corresponding structure of the electronics rack or the subassembly of the electronics rack and the second attachment mechanism moves to the extended position so that a projecting portion of the second attachment mechanism is contained within a holding chamber in the electronics rack or the subassembly of the electronics rack.

Use Example 5: The method according to use example 2, wherein moving the first attachment mechanism of the electronics tray to the retracted position comprises moving an interface group of the first attachment mechanism into contact with and relative to a corresponding structure in the electronics rack or the subassembly of the electronics rack to move the first attachment mechanism to the retracted position against the first biasing force of the first biasing mechanism.

Use Example 6: The method according to use example 5, further including upon moving the interface group of the first attachment mechanism beyond the corresponding structure of the electronics rack or the subassembly of the electronics rack so the interface group no longer contacts the corresponding structure of the electronics rack or the subassembly of the electronics rack and the first attachment mechanism moves to the extended position so that a projecting portion of the first attachment mechanism is contained within a holding chamber in the electronics rack or the subassembly of the electronics rack.

Use Example 7: The method according to use example 1, further including making an electrical connection between the electronic components on the electronics tray with electronic components in the electronics rack or the subassembly of the electronics rack.

Use Example 8: The method according to use example 7, wherein the electrical connection between the electronic components on the electronics tray with electronic components in the electronics rack or the subassembly of the electronics rack is made in response to installation of the electronics tray in the electronics rack or the subassembly of the electronics rack.

Use Example 9: The method according to use example 1, further including: moving each of at least two first engagement members of the first attachment mechanism at the first end of the electronics tray to a respective retracted position wherein each of the at least two first engagement members are unable to secure the electronics tray within the electronics rack or the subassembly of the electronics rack; moving each of at least two second engagement members of the second attachment mechanism at the second end of the electronics tray to a respective extended position wherein each of the at least two second engagement members of the second attachment mechanism are securable within a respective, corresponding different portion of the electronics rack or the subassembly of the electronics rack; and moving each of the at least two engagement members of the first attachment member to a respective extended position wherein each of the at least two first engagement members are securable within a respective, corresponding different portion of the electronics rack or the subassembly of the electronics rack.

Use Example 10: The method according to use example 9, further including moving the at least two engagement members of the first attachment mechanism in a direction different than movement of the electronics tray in response to positioning the electronics tray in the installation position.

Use Example 11: The method according to use example 9, further including moving the at least two engagement members of the second attachment mechanism in a direction substantially perpendicular to the movement of the electronics tray in response to positioning the electronics tray in the installation position.

Use Example 12: A method of installing an electronics tray configured to contain electronic components in an electronics rack or the subassembly of the electronics rack that permits and/or facilitates installation from two different directions, e.g., a front end and a rear end of the electronics rack or the subassembly of the electronics rack, where moving an electronics tray into a first end of the electronics rack or the subassembly of the electronics rack includes: (a) moving a second rear end of the electronics tray into a front end of the electronics rack or the subassembly of the electronics rack by moving the electronics tray in a rearward direction from the front end of the electronics rack or the subassembly of the electronics rack toward a rear end of the electronics rack or the subassembly of the electronics rack; (b) moving, in response to moving the electronics tray in the rearward direction, each of third and fourth engagement members of a second attachment mechanism at a rear end of the electronics tray to a respective retracted position wherein each respective third and fourth engagement member is not securable within the electronics rack or the subassembly of the electronics rack; (c) moving, in response to moving the electronics tray in the rearward direction, each of the third and fourth engagement members past a respective first and second holding chamber formed in the electronics rack or the subassembly of the electronics rack; (d) moving, in response to moving the electronics tray in the rearward direction, first and second engagement members of a first attachment mechanism at a front end of the electronics tray to a respective retracted position wherein each respective first and second engagement member is not securable within the electronics rack or the subassembly of the electronics rack; and (e) moving, in response to further rearward movement of the electronics tray, each respective first and second engagement members into an extended position wherein each respective first and second engagement member is contained within each of the respective first and second holding chambers and moving, in response to further rearward movement of the electronics tray, each respective third and fourth engagement member into an extended position wherein each respective third and fourth engagement member is contained within each of a respective third and fourth holding chamber in the electronics rack or the subassembly of the electronics rack; and moving an electronics tray into the rear end of the electronics rack or the subassembly of the electronics rack includes: (a) moving a front end of the electronics tray into a rear end of the electronics rack or the subassembly of the electronics rack by moving the electronics tray in a frontward direction from the rear end of the electronics tray toward a front end of the electronics rack or the subassembly of the electronics rack; (b) moving, in response to moving the electronics tray in the frontward direction, each of first and second engagement members of a first attachment mechanism at a front end of the electronics tray to a respective retracted position wherein each respective first and third engagement member is not securable within the electronics rack or the subassembly of the electronics rack; (c) moving, in response to moving the electronics tray in the frontward direction, each of the first and second engagement members past a respective third and fourth holding chamber formed in the electronics rack or the subassembly of the electronics rack; (d) moving, in response to moving the electronics tray in the frontward direction, third and fourth engagement members of a second attachment mechanism at a rear end of the electronics tray or the subassembly of the electronics rack to a respective retracted position wherein each respective third and fourth engagement member is not securable within the electronics rack or the subassembly of the electronics rack; and (e) moving, in response to further frontward movement of the electronics tray, each respective first and second engagement members into an extended position wherein each respective first and second engagement member is contained within each of a respective first and second holding chamber and moving, in response to further frontward movement of the electronics tray, each respective third and fourth engagement member into an extended position wherein each respective third and fourth engagement member is contained within each of the third and fourth holding chambers in the electronics rack or the subassembly of the electronics rack.

Use Example 13: A method of removing an electronics tray configured to contain electronic components in an electronics rack or the subassembly of the electronics rack that permits and/or facilitates removal from a first end and a second end, e.g., a front end and a rear end, of the electronics rack or the subassembly of the electronics rack where removing the electronics tray from the front end of the electronics rack or the subassembly of the electronics rack includes: (a) moving, by a user, first and second engagement members of a first attachment mechanism at a front end of the electronics tray to a respective retracted position wherein each respective first and second engagement member is not contained within a respective first holding chamber and a respective second holding chamber in the electronics rack or the subassembly of the electronics rack; (b) moving a front end of the electronics tray in a frontward direction so that the front end of the electronics tray is removed from a front end of the electronics rack or the subassembly of the electronics rack; (c) moving, in response to moving the electronics tray in the frontward direction, each of the first and second engagement members past the respective first and second holding chambers formed in the electronics rack or the subassembly of the electronics rack; (d) moving, in response to moving the electronics tray in the frontward direction, each of third and fourth engagement members of a second attachment mechanism at a rear end of the electronics tray to a respective retracted position wherein each respective third and fourth engagement member is not contained with a respective third holding chamber and fourth holding chamber formed within the electronics rack or the subassembly of the electronics rack; (e) moving, in response to moving the electronics tray in the frontward direction, each of the third and fourth engagement members past the respective third and fourth holding chamber formed in the electronics rack or the subassembly of the electronics rack; and (f) moving, in response to further frontward movement of the electronics tray, each respective third and fourth engagement members into the retracted position and past each respective first and second holding chamber; and removing the electronics tray from the rear end of the electronics rack or the subassembly of the electronics rack includes: (a) moving, by a user, third and fourth engagement members of a second attachment mechanism at a rear end of the electronics tray to a respective retracted position wherein each respective third and fourth engagement member is not contained within a respective third holding chamber and a respective fourth holding chamber in the electronics rack or the subassembly of the electronics rack; (b) moving a rear end of the electronics tray in a rearward direction so that the rear end of the electronics tray is removed from a rear end of the electronics rack or the subassembly of the electronics rack; (c) moving, in response to moving the electronics tray in the rearward direction, each of the third and fourth engagement members past the respective third and fourth holding chambers formed in the electronics rack or the subassembly of the electronics rack; (d) moving, in response to moving the electronics tray in the rearward direction, each of first and second engagement members of a first attachment mechanism at a front end of the electronics tray to a respective retracted position wherein each respective first and second engagement member is not contained with a respective first holding chamber and second holding chamber formed within the electronics rack or the subassembly of the electronics rack; (e) moving, in response to moving the electronics tray in the rearward direction, each of the first and second engagement members past the respective first and second holding chamber formed in the electronics rack or the subassembly of the electronics rack; and (f) moving, in response to further rearward movement of the electronics tray, each respective first and second engagement members into the retracted position and past each respective third and fourth holding chamber.

### Alternative Embodiment

The attachment mechanisms discussed above rely on linear movement to secure and remove the electronics tray from the rack. In an alternative embodiment, the attachment mechanisms may rely on a rotational movement to secure and remove the electronics tray from the rack. For example, first engagement member 140 may rotate upon installation to engage with first holding chamber 106. First engagement member 140 may then be rotated by a user to disengage with first holding chamber 106 to remove the electronics tray from the rack.

### CONCLUSION

The terminology used herein is for the purpose of describing particular implementations only and is not intended to be limiting of this disclosure. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, components, subsystems and/or groups but do not preclude the presence or addition of one or more other features, integers, steps, operations, elements, components, subsystems, and/or groups thereof. Further, the terms up, upper, down, lower, above, below, left, right, forward, rearward, first, second, third, and the like are intended to be understood in the context of the representations described and illustrated above so that a system, device, product, subsystem, and/or component may have such an orientation in reference to the frame or to various elements as supported by the frame or as illustrated in the drawing or figures.

The corresponding structures, materials, acts, and equivalents of all means or step plus function elements, if any, in the claims below are intended to include any structure, material, or act for performing the function in combination with other claimed elements as specifically claimed. The description of the present disclosure has been presented for purposes of illustration and description but is not intended to be exhaustive or limited to this disclosure in the form disclosed. Many modifications and variations will be apparent to those of ordinary skill in the art without departing from the scope and spirit of this disclosure. The various implementations were chosen and described in order to explain the principles of this disclosure and the practical application, and to enable others of ordinary skill in the art to understand this disclosure for various implementations with various modifications as are suited to the particular use contemplated.

What is claimed is:

1. An electronics tray configured to contain multiple electronic components, the electronics tray comprising attachment mechanisms at respective ends of the electronics tray to contain the electronics tray in an electronics rack or subassembly of the electronics rack and permit multi-directional installation and multi-directional removal of the electronics tray from the electronics rack or the subassembly of the electronics rack.

2. The electronics tray according to claim 1, wherein at least one attachment mechanism of the attachment mechanisms comprises a biasing mechanism wherein the biasing mechanism is configured to bias the at least one attachment mechanism to a first extended position where the at least one attachment mechanism is contained within a securing portion of the electronics rack or the subassembly of the electronics rack to secure the electronics tray in the electronics rack or the subassembly of the electronics rack.

3. The electronics tray according to claim 1, wherein at least one attachment mechanism of the attachment mechanisms comprises at least two engagement members on opposite sides of the electronics tray wherein each of the at least two engagement members are configured to be contained within a different securing portion of the electronics rack or the subassembly of the electronics rack to secure the electronics tray within the electronics rack or the subassembly of the electronics rack.

4. The electronics tray according to claim 3, wherein each engagement member comprises an engagement member biasing mechanism to bias a respective engagement member to a first extended position such that each respective engagement member is containable within a respective different securing portion of the electronics rack or subassembly of the electronics rack to secure the electronics tray to the electronics rack or the subassembly of the electronics rack.

5. The electronics tray according to claim 4, wherein each engagement member biasing mechanism comprises a spring element.

6. The electronics tray according to claim 3, wherein the at least two engagement members are moveable to a retracted position where each respective engagement member is configured to not engage the respective different securing portions within the electronics rack or the subassembly of the electronics rack.

7. The electronics tray according to claim 3, wherein each of the at least two engagement members are movable in a direction perpendicular to a direction of moving the electronics tray within the electronics rack or the subassembly of the electronics rack during installation or removal of the electronics tray from the electronics rack or the subassembly of the electronics rack.

8. The electronics tray according to claim 3, wherein each of the at least two engagement members comprises at least one recess to engage at least one projection associated with the electronics tray to guide movement of each respective engagement member relative to the electronics tray.

9. The electronics tray according to claim 3, wherein at least one engagement member comprises an interface group configured to contact corresponding structure in the electronics rack or the subassembly of the electronics rack in response to moving the electronics tray to move the at least one engagement member against a biasing force applied by an engagement member biasing mechanism so that the at least one engagement member is configured to not be contained in a securing portion in the electronics rack or the subassembly of the electronics rack, wherein the interface group consists of at least one of: an inclined surface, a rounded surface, a roller, and combinations thereof.

10. The electronics tray according to claim 9, wherein the at least one engagement member comprises an engagement surface configured to inhibit movement of the electronics tray by contacting an engaging surface in the electronics rack or the subassembly of the electronics rack.

11. The electronics tray according to claim 10, wherein the securing portion comprises a holding chamber formed by:
an engaging surface of the electronics rack or the subassembly of the electronics rack that interacts with the engagement surface of the at least one engagement member configured to inhibit movement of the electronics tray, and
at least one of a structure group of the electronics rack or subassembly of the electronics rack configured to move the at least one engagement member to permit movement of the electronics tray, the structure group consisting of an inclined surface, a rounded surface, rollers, and combinations thereof.

12. The electronics tray according to claim 9, wherein the at least one engagement member is configured to move against a biasing force of an engagement member biasing mechanism in response to moving the electronics tray within the electronics rack or the subassembly of the electronics rack.

13. The electronics tray according to claim 12, wherein the at least one engagement member is configured to be user moveable to a retracted position where the engagement member is not contained in the securing portion of the electronics rack or the subassembly of the electronics rack.

14. A method of installing an electronics tray containing a plurality of electronics components in an electronics rack or a subassembly of the electronics rack comprising:
moving a first attachment mechanism at a first end of the electronics tray to a retracted position wherein the first attachment mechanism is not securable within the electronics rack or the subassembly of the electronics rack;
moving the electronics tray into an installation position in the electronics rack or the subassembly of the electronics rack;
moving the first attachment mechanism, in response to the electronics tray being located in the installation position in the electronics rack or the subassembly of the electronics rack, to an extended position where the first attachment mechanism is contained within a first securing portion of the electronics rack or the subassembly of the electronics rack; and
moving a second attachment mechanism at a second end of the electronics tray, in response to the electronics tray being located in the installation position in the electronics rack or the subassembly of the electronics rack, to an extended position where the second attachment mechanism is contained within a second different securing portion of the electronics rack or the subassembly of the electronics rack.

15. The method according to claim 14, further comprising:
moving the first attachment mechanism of the electronics tray to the retracted position against a first biasing force of a first biasing mechanism configured to move the first attachment mechanism to the extended position; and
moving the second attachment mechanism of the electronics tray to the retracted position against a second biasing force of a second biasing mechanism configured to move the second attachment mechanism to the extended position.

16. The method according to claim 15, wherein moving the second attachment mechanism of the electronics tray to the retracted position comprises moving an interface group of the second attachment mechanism into contact with and relative to a corresponding structure in the electronics rack or the subassembly of the electronics rack to move the second attachment mechanism to the retracted position against the second biasing force of the second biasing mechanism, wherein the interface group consists of at least one of: an inclined surface, a rounded surface, a roller, and combinations thereof.

17. The method according to claim 16, further comprising:
moving the interface group of the second attachment mechanism beyond the corresponding structure in the electronics rack or the subassembly of the electronics rack so the interface group no longer contacts the corresponding structure of the electronics rack or the subassembly of the electronics rack; and
moving, in response to moving the interface group of the second attachment mechanism beyond the corresponding structure in the electronics rack or the subassembly of the electronics rack so the interface group no longer contacts the corresponding structure of the electronics rack or the subassembly of the electronics rack, the second attachment mechanism to the extended position so that a projecting portion of the second attachment mechanism is contained within a holding chamber in the electronics rack or the subassembly of the electronics rack.

18. The method according to claim 15, wherein moving the first attachment mechanism of the electronics tray to the retracted position comprises moving an interface group of the first attachment mechanism into contact with and relative to a corresponding structure in the electronics rack or the subassembly of the electronics rack to move the first attachment mechanism to the retracted position against the first biasing force of the first biasing mechanism, wherein the interface group consists of at least one of: an inclined surface, a rounded surface, a roller, and combinations thereof.

19. The method according to claim 18, further comprising:
moving the interface group of the first attachment mechanism beyond the corresponding structure of the electronics rack or the subassembly of the electronics rack so the interface group no longer contacts the corresponding structure of the electronics rack; and
moving, in response to moving the interface group of the first attachment mechanism beyond the corresponding structure of the electronics rack or the subassembly of the electronics rack so the interface group no longer contacts the corresponding structure of the electronics rack, the first attachment mechanism to the extended position so that a projecting portion of the first attachment mechanism is contained within a holding chamber in the electronics rack or the subassembly of the electronics rack.

20. The method according to claim 14, further comprising:
moving at least two first engagement members of the first attachment mechanism at the first end of the electronics tray to a respective retracted position wherein each of the at least two first engagement members are configured not to secure the electronics tray within the electronics rack or the subassembly of the electronics rack;
moving at least two second engagement members of the second attachment mechanism at the second end of the electronics tray to a respective extended position wherein each of the at least two second engagement members of the second attachment mechanism are secured within a respective, corresponding different portion of the electronics rack or the subassembly of the electronics rack; and
moving each of the at least two first engagement members of the first attachment mechanism to a respective extended position wherein each of the at least two first engagement members are secured within a respective, corresponding different portion of the electronics rack or the subassembly of the electronics rack.
